(19) United States
(12) Patent Application Publication
(10) Pub. No.: US 2012/0152322 A1
(43) Pub. Date: Jun. 21, 2012

(54) VERTICAL JUNCTION PV CELLS

(75) Inventors: Abraham KRIBUS, Rechovot (IL); Yossi Rosenwaks, Hod-HaSharon (IL); Rona Sarfaty, Haifa (IL); Gideon Segev, Beer-Sheva (IL)

(73) Assignees: Ofek Eshkolot Research and Development Ltd., Carmiel (IL); Ramot at Tel-Aviv University Ltd., Te-Aviv (IL)

(21) Appl. No.: 13/298,396

(22) Filed: Nov. 17, 2011

Related U.S. Application Data
(63) Continuation-in-part of application No. PCT/IB2010/052196, filed on May 18, 2010.
(60) Provisional application No. 61/282,184, filed on Dec. 28, 2009.
(60) Provisional application No. 61/272,643, filed on Oct. 15, 2009.
(60) Provisional application No. 61/179,420, filed on May 19, 2009.

(51) Int. Cl. H01L 31/05; H01L 31/18

(52) U.S. Cl. 136/249; 438/73; 257/E31.032

(57) ABSTRACT

A monolithic semiconductor solar cell including a semiconductor layer including a plurality of pores, wherein walls of the pores are doped, forming vertical junctions between the walls of the pores and a bulk of the semiconductor, the pores each contain a conductor which is in electrical contact with the walls of the pores, and the conductors of the pores are electrically interconnected to provide an output voltage of the solar cell. A monolithic semiconductor solar cell including a semiconductor layer including a plurality of trenches, wherein walls of the trenches are doped, forming vertical junctions between the walls of the trenches and a bulk of the semiconductor, the trenches each contain a conductor which is in electrical contact with the walls of the trenches, and the conductors of the trenches are electrically interconnected to provide an output voltage of the solar cell. Related apparatus and methods are also described.

### RELATED APPLICATIONS

This application is a continuation-in-part (CIP) of PCT Patent Application No. PCT/IB2010/052196 having International filing date of May 18, 2010, which claims the benefit of priority of U.S. Provisional Patent Application Nos. 61/282,184 filed on Dec. 28, 2009, 61/272,643 filed on Oct. 15, 2009, and 61/179,420 filed on May 19, 2009. The contents of the above applications are all incorporated herein by reference.

### FIELD AND BACKGROUND OF THE INVENTION

The present invention, in some embodiments thereof, relates to a photovoltaic cell design and, more particularly, but not exclusively, to a monolithic photovoltaic cell design.

The leading solar energy technology is a direct conversion of sunlight to electricity using photovoltaic cells, usually with cells based on single-crystal silicon. However, this technology is not very efficient (less than 20% conversion efficiency for commercially available solar panels), and quite expensive (solar electricity today is about four times more expensive than electricity from fossil fuels). Nevertheless, the photovoltaic industry is growing in the last few years. But this growth is fueled by government subsidies and not by a real competitive position in the energy market.

Several paths towards competitive solar electricity are under development around the world. Most notable are:
Thin-film cells, which use significantly smaller amounts of the expensive semiconductor material; but they usually offer lower efficiency and are facing questions of long-term stability
Concentrator systems, usually coupled with advanced multi-junction cells, offering higher efficiency (up to 30%) and reduced amount of semiconductor material (down to 1/1000 of the collector area); however they use only direct sunlight and are therefore not suitable for use in many relevant locations
Organic based materials (e.g., polymer, dye sensitized), using low-cost photoactive materials, but still suffering from low efficiency and short lifetime

Several groups have been working on monolithic cells to obtain a high output voltage (Voc). Including, S. Keller et al. from the University of Konstanz who have reported a Voc of 2.8 V [3], P. Ortega et al., who obtained Voc of 103 V [11], and

S. Van Riesen et al. who fabricated GaAs (Gallium Arsenide) Monolithic integrated modules (MIM modules) with efficiency above 20%, and an open circuit voltage of over 30 Volt [6, 13].

The following articles may also be of some relevance:

1. Woyte A., Nijs J., Belmans R. (2003) Partial shadowing of photovoltaic arrays with different system configurations: literature review and field test results. Solar Energy 74, 217-233; herein also as ‘[1]’.

2. Kreske K. (2002) Optical design of a solar flux homogenizer for concentrator photovoltaics. Appl. Optics 41, 2053-8; herein also as ‘[2]’.

3. S. Keller, S. Scheibenstock, P. Fath, G. Willeke, and E. Bucher Theoretical and experimental behavior of monolithically integrated crystalline silicon solar cells, J. Appl. Phys. 87, 1556 (2000); herein also as ‘[3]’.

4. Lee J B, Chen Z, Allen M G, Rohatgi A, Arya R. A miniaturized high voltage solar cell array as an electrostatic MEMS power supply. Journal of Microelectromechanical Systems 1995; 4(3): 102-108; herein also as ‘[4]’.

5. Ford D H, Rand J A, Barnett A M, Delle Donne E J, Ingram A E, Hall R R. Development of light-trapped, interconnected, silicon-film modules. Proceedings of the 26th IEEE Photovoltaic Specialists Conference, 1997; 631-634; herein also as [5].

6. S. Van Riesen et al., Proceedings of the 19th European Photovoltaic Solar Energy Conference, 2004; herein also as ‘[6]’.

7. Gover A. Stella P. (1974) Vertical multijunction solar cell one dimensional analysis. IEEE Trans. Elect. Devices 21, 351-6; herein also as ‘[7]’.

8. Sater B. L. (1982) High intensity solar cell. U.S. Pat. No. 4,332,973; herein also as ‘[8]’.

9. Ries H., Gordon J. M., Lasken M. (1997) High-flux photovoltaic solar concentrators with kaleidoscope-based optical designs. Solar Energy 60, 11-16; herein also as ‘[9]’.

10. Nishioka K., Takamoto T., Agui T., Kaneiwa M., Uraoka Y., Fuyuki T. (2006) Evaluation of InGaP/InGaAs/Ge triple-junction solar cell and optimization of solar cell's structure focusing on series resistance for high-efficiency concentrator photovoltaic systems. Solar Energy Mat. Solar Cells 90, 1308-21; herein also as ‘[10]’.

11. Ortega P., Bermejo S., Castaner L. (2008) High Voltage Photovoltaic Mini-modules. Prog. Photovolt: Res. Appl. 10.1002; herein also as ‘[11]’.

12. Keevers M. J. P, Prog. Photovolt: Res. Appl. 2000; 8: 579-589; S. van Riesen, F. Dimroth and A. W. Bett, Fabrication of MIM-GaAs Solar Cell for High Concentration PV, 3rd World Conference on PV Energy Conversion, May 11-18 2003; herein also as ‘[12]’.

13. R. Lockenhoff et al., Proceedings of the IEEE 4th World Conference on Photovoltaic Energy Conversion, 2006.

14. II-V multijunction solar cells for concentrating photovoltaics, Hector Cotal, Chris Fetzer, et al., Energy Environ. Sci., 2009, 2, 174-192.

15. Evaluation of InGaP/InGaAs/Ge triple-junction solar cell and optimization of solar cell's structure focusing on series resistance for high-efficiency concentrator photovoltaic systems, Kensuke Nishioka, Tatsuya Takamoto et al., Solar Energy Materials & Solar Cells 90 (2006) 1308-1321.

16. Development of a Fabrication Process for Parallel Multijunction Thin Film Silicon Solar Cells on Wafer Substrates, Mark J. Keevers, Prog. Photovolt. Res. Appl. (2000) vol. 8, pp. 579-589.

17. R. Pozner, G. Segev, R. Sarfaty, A. Kribus, and Y. Rosenwaks, “Vertical junction Si cells for concentrating photovoltaics,” Progress in Photovoltaics, In Press, DOI: 10.1002/pip.1118, 2011, herein also as ‘[17]’.

18. B. L. Sater and N. D. Sater, “High voltage silicon VMJ solar cells for up to 1000 suns intensities,” in 29 IEEE Photovoltaic specialist conf., New Orleans, 2002, herein also as ‘[18]’.

19. W. P. Mulligan, A. Terao, D. D. Smith, P. J. Verlinden, and R. M. Swanson, “Development of chip-size silicon solar cells,” in 28 IEEE Photovoltaic Specialists Conference, 2000, pp. 158-163, herein also as ‘[19]’.

### SUMMARY OF THE INVENTION

The present invention, in some embodiments thereof, relates to a photovoltaic cell design and, more particularly, but not exclusively, to some monolithic photovoltaic cell designs, for example, a multi-junction and/or vertical junction designs.

There is provided in accordance with an exemplary embodiment of the invention, a monolithic solar cell, comprising a plurality of semiconductor junctions defining an interface between two materials, said junctions adapted to generate an electric potential when a surface thereof is exposed to electromagnetic radiation and wherein said junctions are vertical junctions with at least 30% of said interface being within 30 degrees of a radiation incidence angle thereon.

In an exemplary embodiment of the invention the monolithic cell comprises junctions formed in one substance piece. Alternatively, the monolithic cell comprises junctions formed in a plurality of substance pieces attached to form one piece, for example only, 2, 3, 4, 5, 10 or intermediate number of pieces. Optionally, the junctions are separated by generally vertical trenches. Optionally the vertical cross-section of a trench is at least one of a rectangular, triangular, trapezoid or cylindrical. Optionally or alternatively, the junctions are formed by doping sides of the trenches. Optionally or alternatively, the sides of a trench are differently doped.

In an exemplary embodiment of the invention, said cell is constructed by interleaving a plurality of sets comprising a plurality of spaced apart junctions. Optionally, a junction in a set complementarily fits between two junctions of another set. Optionally or alternatively, a conductor is sandwiched between two interleaved junctions. Optionally or alternatively, a plurality of sets comprises two sets.

In an exemplary embodiment of the invention, the junctions are formed in pores formed on a substrate.

In an exemplary embodiment of the invention, said plurality of junctions are formed of identical materials.

In an exemplary embodiment of the invention, each junction is formed of a same material with two doping profiles.

In an exemplary embodiment of the invention, said junctions are arranged so at least 99% of said surface is exposed to said radiation and within a diffusion length from said interface of the junction.

In an exemplary embodiment of the invention, said junctions are formed on a single underlying layer of material. Optionally, said layer of material is silicon. Optionally, said junctions are thin film junctions.

In an exemplary embodiment of the invention, said junctions are arranged in a plane.

In an exemplary embodiment of the invention, said plurality of junctions includes at least 50 junctions per linear cm of the cell. Optionally or alternatively, said plurality of junctions includes at least 450 junctions per linear cm of the cell.

In an exemplary embodiment of the invention, said cell generates between 100 and 1000 volts.

In an exemplary embodiment of the invention, said cell includes at least some junctions connected in series as groups and said groups connected in parallel.

In an exemplary embodiment of the invention, said junctions are arranged along a surface of the cell so that less than 5% of an area of said cell surface is hidden from said radiation.

In an exemplary embodiment of the invention, the cell comprises a plurality of conductors sandwiched between said junctions and arranged to have a thin aspect along said surface

In an exemplary embodiment of the invention, said thin aspect is thinner than 2 microns. Optionally or alternatively, said thin aspect thins in a direction of said surface.

In an exemplary embodiment of the invention, said junctions are arranged along a surface and comprising at least one back contact on an opposite side of said surface, said back contact having an electrical connection to at least one of said junctions.

In an exemplary embodiment of the invention, said cell generates a voltage per unit cell length of at least 30 V/cm. Optionally or alternatively, said cell generates a voltage per unit cell length of at least 300 V/cm. Optionally or alternatively, said cell generates a voltage per unit cell length of at least 500 V/cm. Optionally or alternatively, said cell generates a voltage per unit cell length of at least 900 V/cm.

In an exemplary embodiment of the invention, the cell comprises a second plurality of junctions with different sensitivity to electromagnetic radiation and wherein said plurality of junctions and said second plurality of junctions are arranged in at least two layers. Optionally, the number of junctions in one layer is different from the number of junctions in a second layer, and the numbers of junctions are adjusted so that the overall voltage provided by the first and second layers is substantially equal.

In an exemplary embodiment of the invention, said cell is mounted on a mounting structure so as to receive electromagnetic radiation from at least the two largest surfaces thereof.

In an exemplary embodiment of the invention, each of said junctions has a ratio of volume between said materials of at least 1:4.

In an exemplary embodiment of the invention, there is provided a solar energy system including a plurality of cells as described herein mounted on a mounting structure and forming a panel, wherein the cells are electrically connected in parallel.

In an exemplary embodiment of the invention, there is provided a solar energy system including a plurality of cells as described herein mounted on a mounting structure and forming a panel, wherein the cells are electrically connected in parallel and in series and wherein the largest number of elements consisting of cells or groups connected in series, are fewer than six.

In an exemplary embodiment of the invention, there is provided a solar energy module including:

at least one cell as described herein; and concentration optics, which aim light at said cell. Optionally, said concentration optics aim light to be uniform to within 20% by amplitude, only over less than 80% of a cross-section of said light. Optionally, said concentration optics concentrate by at least 700 suns.

In an exemplary embodiment of the invention, a solar energy system includes a plurality of modules as described herein, mounted on a mounting structure, wherein the cells are electrically connected in parallel.

In an exemplary embodiment of the invention, there is provided a solar energy system including a plurality of modules as described herein mounted on a mounting structure, wherein the cells are electrically connected in parallel and in series and wherein the largest number of elements consisting of cells or groups connected in series, are fewer than six.

In an exemplary embodiment of the invention, there is provided a solar energy receiver including a plurality of cells as described herein mounted on a mounting structure, wherein the cells are electrically connected in parallel.

In an exemplary embodiment of the invention, there is provided a solar energy receiver including a plurality of cells as described herein mounted on a mounting structure, wherein the cells are electrically connected in parallel and in series and wherein the largest number of elements consisting of cells or groups connected in series, are fewer than six.

In an exemplary embodiment of the invention, there is provided a solar energy system including a plurality of receivers as described herein connected at least partly in parallel.

In an exemplary embodiment of the invention, a solar energy module has an at least one cell comprises a plurality of cells connected electrically in parallel.

There is provided in accordance with an exemplary embodiment of the invention, a monolithic solar cell, comprising a plurality of semiconductor junctions defining an interface between two materials, said junctions adapted to generate an electric potential when exposed to electromagnetic radiation and said junctions are arranged so that at least 95% of the surface of both materials that are directed to said radiation are exposed to said radiation for each junction and are within a diffusion length from the interface of the materials, wherein said junctions are manufactured together in said monolithic form. Optionally, said materials are thick enough to absorb at least 80% of radiation impinging thereon in a bandgap wavelength thereof. Optionally or alternatively, said junctions are vertical junctions with at least 30% of an interface area between said materials being within 30 degrees of a design radiation incidence angle, thereon. Alternatively, said design radiation angle is perpendicular to a base of said cell.

There is provided in accordance with an exemplary embodiment of the invention, a monolithic solar cell, comprising a plurality of junctions defining an interface between two materials formed about walls of pores formed in a substrate. Optionally, the pores are arranged in a plurality of patterns enabling currents flow between a junction and junctions immediately around said junction. Optionally or alternatively, a current flows between junctions formed of the same material with different doping profiles. Optionally or alternatively, the pores are filled with an electrical conductor.

There is provided in accordance with an exemplary embodiment of the invention, a method of manufacturing a solar cell, comprising: monolithically manufacturing a plurality of vertical junctions; and forming metal contacts sandwiched between the junctions. Optionally, said contacts form a series connection between junctions. Optionally or alternatively, the method comprises providing at least one back contact electrically connected to at least one junction. Optionally or alternatively, the method comprises forming the plurality of junctions in a plurality of generally parallel layers each comprising a plurality of junctions.

There is provided in accordance with an exemplary embodiment of the invention, a method of manufacturing a solar cell, comprising:

monolithically manufacturing a at least two sets of a plurality of spaced apart vertical junctions;

interleaving the plurality of junctions of each set in the space between the junctions in another set; and

forming electrical conducting contacts sandwiched between the junctions. Optionally, at least two sets comprises two sets.

There is provided in accordance with an exemplary embodiment of the invention, a method of manufacturing a solar cell, comprising:

monolithically manufacturing a plurality of vertical junctions formed in pores arranged in a plurality of patterns enabling currents flow between a junction and junctions immediately around said junction. Optionally, the method comprises forming electrical conducting contacts inside the pores.

There is provided in accordance with an exemplary embodiment of the invention, a method of manufacturing a solar cell, comprising:

forming a plurality of pores or trenches in a substrate; and

differently doping different parts of a same pore or trench.

In accordance with an exemplary embodiment of the invention, there is provided a photovoltaic cell having a geometry in which most (e.g., >94%, >95%, >98%, >99%) of the radiation hitting the cell hits active portions that are both near a boundary part of a junction of the cell and directly exposed to incoming light. Optionally, the cell is monolithic or formed of monolithic sections with multiple junctions (e.g., >2, >10, >100 junctions per monolithic element). In an exemplary embodiment of the invention, the cell is formed of a plurality of vertical junctions connected in series.

In an exemplary embodiment of the invention, the cell design decouples optical and electronic effects and allows better collection of generated carriers. In an exemplary embodiment of the invention, substantially all junctions in a cell are near the boundary part.

As used herein, vertical junctions include also junctions whose inner boundary between materials is not strictly vertical. For example, the junction can be at an angle of up to 30 degrees, or the junction may include one or more horizontal or near horizontal components, for example, of up to, 30%, 50%, 70% in area. A particular benefit of using vertical junctions, as utilized in some embodiments of the invention, is that the junction materials can be thick enough to absorb radiation, while still being mostly or completely in the field region of the junction and allowing direct radiation impinging on the junction materials.

In an exemplary embodiment of the invention, the above percentages of material are within a diffusion length of the junction, optionally, within less than a diffusion length, for example, 30%, 50%, 70 or 90% of a diffusion length, or intermediate percentages. Alternatively, the above percentages are within more than a diffusion length, for example, 110%, 120% of a diffusion length.

In an exemplary embodiment of the invention, the cell junctions are thick enough to absorb, for example, at least 70%, 80%, 90% of impinging radiation at wavelengths that significantly interact with the materials used in the junctions. Optionally, the distance of travel required by generated carriers is reduced as compared to stacked cells, for example, being 50%, 30%, 20% or less, on the average.

In an exemplary embodiment of the invention, electrical conductors are sandwiched between junctions in a way which reduces or minimizes their cross-section relative to incoming radiation, for example, to block less than 5%, 3% or 1% of incoming radiation. Optionally, the conductors have a thickness that varies as a function of distance from the radiation receiving face.

In an exemplary embodiment of the invention, at least some electrical conductors are wrapped around a bottom of the cell, to support electrical coupling, as part of an array with parallel or series or mixed parallel/series electrical connection between cells.

Optionally or alternatively, a plurality of cell layers (e.g., 2, 3, 4, 5, or more) is vertically stacked, with each layer being sensitive to different portion of the solar spectrum. Optionally or alternatively, the cell is arranged to receive radiation from opposite faces thereof.

There is provided in accordance with an exemplary embodiment of the invention, a monolithic solar cell, comprising a plurality of semiconductor junctions defining a boundary between two materials, said junctions adapted to generate an electric potential when exposed to electromagnetic radiation and wherein said junctions are vertical junctions with at least 30% of said boundary being within 30 degrees of a design radiation incidence angle, thereon.

In an exemplary embodiment of the invention, said plurality of junctions are formed of identical materials.

In an exemplary embodiment of the invention, each junction is formed of a same material with two doping profiles.

In an exemplary embodiment of the invention, said junctions are arranged so at least 99% of said surface is exposed to said radiation and within a diffusion length from said boundary of the junction.

In an exemplary embodiment of the invention, said junctions are formed on a single underlying layer of material. Optionally, said layer of material is silicon.

In an exemplary embodiment of the invention, said junctions are thin film junctions. Optionally or alternatively, said junctions are arranged in a plane.

In an exemplary embodiment of the invention, said plurality of junctions includes at least 50 junctions per linear cm of the cell.

In an exemplary embodiment of the invention, said plurality of junctions includes at least 450 junctions per linear cm of the cell.

In an exemplary embodiment of the invention, said junctions are arranged along a surface of the cell so that less than 5% of an area of said cell surface is hidden from said radiation. Optionally, the cell comprises a plurality of conductors sandwiched between said junctions and arranged to have a thin aspect thereof along said surface. Optionally, said thin aspect is thinner than 2 microns. Optionally or alternatively, said thin aspect thins in a direction of said surface.

In an exemplary embodiment of the invention, said junctions are arranged along a surface and comprising at least one back contact on an opposite side of said surface, said back contact having an electrical connection to at least one of said junctions.

In an exemplary embodiment of the invention, said cell generates a voltage per unit cell length of at least 30 V/cm.

In an exemplary embodiment of the invention, said cell generates a voltage per unit cell length of at least 300 V/cm.

In an exemplary embodiment of the invention, said cell generates a voltage per unit cell length of at least 500 V/cm.

In an exemplary embodiment of the invention, said cell generates a voltage per unit cell length of at least 900 V/cm.

In an exemplary embodiment of the invention, the cell comprises a second plurality of junctions with different sensitivity to electromagnetic radiation and wherein said plurality of junctions and said second plurality of junctions are arranged in at least two layers. Optionally, the number of junctions in one layer is different from the number of junctions in a second layer, and the numbers of junctions are adjusted so that the overall voltage provided by the first and second layers is substantially equal.

In an exemplary embodiment of the invention, said cell is mounted on a mounting structure so as to receive electromagnetic radiation from at least the two largest surfaces thereof.

In an exemplary embodiment of the invention there is provided a solar energy system including a plurality of cells as described herein mounted on a mounting structure and forming a panel, wherein the cells are electrically connected in parallel.

In an exemplary embodiment of the invention there is provided a solar energy system including a plurality of cells as described herein mounted on a mounting structure and forming a panel, wherein the cells are electrically connected in parallel and in series and wherein the largest number of elements consisting of cells or groups connected in series, are fewer than six.

There is provided in accordance with an exemplary embodiment of the invention, a solar energy module including:

at least one cell as described herein; and

concentration optics, which aim light at said cell. Optionally, said concentration optics aim light to be uniform to within 20% by amplitude, over less than 80% of a cross-section of said light.

In an exemplary embodiment of the invention, there is provided a solar energy system including a plurality of modules as described herein, mounted on a mounting structure, wherein the cells are electrically connected in parallel.

In an exemplary embodiment of the invention, there is provided a solar energy system including a plurality of modules as described herein, mounted on a mounting structure, wherein the cells are electrically connected in parallel and in series and wherein the largest number of elements consisting of cells or groups connected in series, are fewer than six.

In an exemplary embodiment of the invention, there is provided a solar energy receiver including a plurality of cells as described herein mounted on a mounting structure, wherein the cells are electrically connected in parallel.

In an exemplary embodiment of the invention, there is provided a solar energy receiver including a plurality of cells as described herein mounted on a mounting structure, wherein the cells are electrically connected in parallel and in series and wherein the largest number of elements consisting of cells or groups connected in series, are fewer than six.

In an exemplary embodiment of the invention, there is provided a solar energy system comprising a plurality of receivers as described herein, connected at least partly in parallel.

In an exemplary embodiment of the invention, the at least one cell comprises a plurality of cells connected electrically in parallel.

There is provided in accordance with an exemplary embodiment of the invention, a method of manufacturing a solar cell, comprising:

monolithically manufacturing a plurality of vertical junctions; and

forming metal contacts sandwiched between the junctions. Optionally, said contacts form a series connection between junctions. Optionally or alternatively, the method comprises providing at least one back contact electrically connected to at least one junction.

There is provided in accordance with an exemplary embodiment of the invention, a monolithic solar cell, comprising a plurality of semiconductor junctions defining a boundary between two materials, said junctions adapted to generate an electric potential when exposed to electromagnetic radiation and said junctions are arranged so that at least 95% of the surface of both materials that are directed to said radiation are exposed to said radiation for each junction and in within a diffusion length from the boundary of the materials, wherein said junctions are manufactured together in said monolithic form. Optionally, said materials are thick enough to absorb at least 80% of radiation impinging thereon in a bandgap wavelength thereof. Optionally, said junctions are vertical junctions with at least 30% of a boundary area between said materials being within 30 degrees of a design radiation incidence angle, thereon. Optionally, said design radiation angle is perpendicular to a base of said cell.

According to an aspect of some embodiments of the present invention there is provided a monolithic semiconductor solar cell including a semiconductor layer including a plurality of pores, wherein walls of the pores are doped, forming vertical junctions between the walls of the pores and a bulk of the semiconductor, the pores each contain a conductor which is in electrical contact with the walls of the pores, and the conductors of the pores are electrically interconnected to provide an output voltage of the solar cell.

According to some embodiments of the invention, some of the walls of the pores are doped with P+ doping, and some of the walls of the pores are doped with N+ doping.

According to some embodiments of the invention, nearest neighbors of a P+ doped pore are N+ doped pores, and nearest neighbors of an N+ doped pore are P+ doped pores.

According to some embodiments of the invention, at least some of the conductors of the P+ doped pores are electrically interconnected to each other, forming a parallel connection of one polarity of the vertical junctions, and at least some of the conductors of the N+ doped pores are electrically interconnected to each other, forming a separate parallel connection of another polarity of the vertical junctions.

According to some embodiments of the invention, including at least two groups of pores, each group including at least one P+ pore and at least one N+ pore, where each of the groups is electrically isolated from the other groups by isolation trenches in the semiconductor.

According to some embodiments of the invention, the conductors of the P+ doped pores in one group are electrically interconnected to conductors of the N+ doped pores in another group, the interconnections alternating P+ and N+ doped pores, forming a serial connection of vertical junctions.

According to some embodiments of the invention, the depth of the pores is substantially equal to a thickness of the semiconductor layer.

According to some embodiments of the invention, the depth of the pores is less than a thickness of the semiconductor layer.

According to an aspect of some embodiments of the present invention there is provided a method of manufacturing a monolithic semiconductor solar cell including forming a plurality of pores in the semiconductor, doping walls of the pores, forming vertical junctions between the walls of the pores and a bulk of the semiconductor, adding a conductor in contact with the doped walls in each pore, electrically interconnecting the conductors to provide an output voltage of the solar cell.

According to some embodiments of the invention, the doping includes doping some of the walls of the pores with P+ doping, and some of the walls of the pores with N+ doping.

According to some embodiments of the invention, the electrically interconnecting includes electrically interconnecting at least some of the conductors of the P+ doped pores to each other, forming a parallel connection of vertical junctions, and electrically interconnecting at least some of the conductors of the N+ doped pores to each other, forming a separate parallel connection of vertical junctions.

According to some embodiments of the invention, further including producing isolation trenches in the semiconductor, to electrically isolate between a plurality of groups of pores, each group of pores including at least one P+ doped pore and at least one N+ doped pore.

According to some embodiments of the invention, the electrically interconnecting includes electrically interconnecting the conductors of the P+ doped pores in one group of pores to the conductors of the N+ doped pores in another group of pores, the interconnections alternating P+ and N+ doped pores, forming a serial connection of vertical junctions.

According to an aspect of some embodiments of the present invention there is provided a monolithic semiconductor solar cell including a semiconductor layer including a plurality of trenches, wherein walls of the trenches are doped, forming vertical junctions between the walls of the trenches and a bulk of the semiconductor, the trenches each contain a conductor which is in electrical contact with the walls of the trenches, and the conductors of the trenches are electrically interconnected to provide an output voltage of the solar cell.

According to an aspect of some embodiments of the present invention there is provided a monolithic solar cell, including a plurality of semiconductor junctions defining an interface between two materials, the junctions adapted to generate an electric potential when a surface thereof is exposed to electromagnetic radiation and wherein the junctions are vertical junctions with at least 30% of the interface being within 30 degrees of a radiation incidence angle thereon, the junctions are separated by generally vertical trenches, and the sides of a trench are differently doped.

According to some embodiments of the invention, the junctions are arranged so at least 99% of the surface is exposed to the radiation and within a diffusion length from the interface of the junction.

According to some embodiments of the invention, the cell includes at least some junctions connected in series as groups and the groups connected in parallel.

According to some embodiments of the invention, the cell generates a voltage per unit cell length of at least 50 V/cm.

According to some embodiments of the invention, including a second plurality of junctions with different sensitivity to electromagnetic radiation and wherein the plurality of junctions and the second plurality of junctions are arranged in at least two layers.

According to some embodiments of the invention, where the number of junctions in one layer is different from the number of junctions in a second layer, and the numbers of junctions are adjusted so that the overall voltage provided by the first and second layers is substantially equal.

According to an aspect of some embodiments of the present invention there is provided a monolithic solar cell, including a plurality of semiconductor junctions defining an interface between two materials, the junctions adapted to generate an electric potential when exposed to electromagnetic radiation and the junctions are arranged so that at least 95% of the surface of both materials that are directed to the radiation are exposed to the radiation for each junction and are within a diffusion length from the interface of the materials, wherein the junctions are manufactured together in the monolithic form.

According to some embodiments of the invention, the materials are thick enough to absorb at least 80% of radiation impinging thereon in a bandgap wavelength thereof.

According to an aspect of some embodiments of the present invention there is provided a monolithic solar cell, including a plurality of junctions defining an interface between two materials formed about walls of pores formed in a substrate.

According to some embodiments of the invention, the pores are arranged in a plurality of patterns enabling currents flow between a junction and junctions immediately around the junction.

According to an aspect of some embodiments of the present invention there is provided a method of manufacturing a solar cell, including monolithically manufacturing a plurality of vertical junctions, and forming metal contacts sandwiched between the junctions.

According to an aspect of some embodiments of the present invention there is provided a method of manufacturing a solar cell, including monolithically manufacturing a at least two sets of a plurality of spaced apart vertical junctions, interleaving the plurality of junctions of each set in the space between the junctions in another set, and forming electrical conducting contacts sandwiched between the junctions.

According to an aspect of some embodiments of the present invention there is provided a method of manufacturing a solar cell, including monolithically manufacturing a plurality of vertical junctions formed in pores arranged in a plurality of patterns enabling currents flow between a junction and junctions immediately around the junction.

According to some embodiments of the invention, including forming electrical conducting contacts inside the pores.

According to an aspect of some embodiments of the present invention there is provided a method of manufacturing a solar cell, including forming a plurality of pores or trenches in a substrate, and differently doping different parts of a same pore or trench.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention, for example, manufacture of panels, can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data.

Optionally, a network connection is provided as well. A display and/or a user input device such as a keyboard or mouse are optionally provided as well.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

Identical or duplicate or equivalent or similar structures, elements, or parts that appear in one or more drawings are generally labeled with the same reference numeral, optionally with an additional letter or letters to distinguish between similar objects or variants of objects, and may not be repeatedly labeled and/or described.

In the drawings:

FIG. 1A is a schematic top view of a prior art horizontal junction MIM;

FIG. 1B is a schematic side cross section view of a prior art horizontal junction MIM;

FIG. 2 is a schematic showing of a structure of a Vertical Multi-Junction, in accordance with an exemplary embodiment of the invention;

FIG. 3A is a schematic showing of a Vertical Multi-Junction with integrated back contacts, in accordance with an exemplary embodiment of the invention;

FIG. 3B is a schematic showing of a Vertical Multi-Junction with soldered back contacts, in accordance with an exemplary embodiment of the invention;

FIG. 4 is a schematic showing of a tandem multi-terminal stacked Vertical Multi-Junction, in accordance with an exemplary embodiment of the invention;

FIG. 5 is a schematic showing of a substrate layout for a module with parallel Vertical Multi-Junction cells, in accordance with an exemplary embodiment of the invention;

FIG. 6 schematically illustrates a VMJ cell construction with a mix of series and parallel internal connections, in accordance with an exemplary embodiment of the invention;

FIG. 7 schematically illustrates groundwork for a design for a VMJ multi-terminal of a plurality of different material PV cell, in accordance with an exemplary embodiment of the invention;

FIG. 8 schematically illustrates side view of the structure of the junctions and contacts at the various depths formed in the groundwork (bulk) as of FIG. 7, in accordance with an exemplary embodiment of the invention;

FIGS. 9A-C schematically illustrate top views of the structure as of FIG. 8 of junctions and contacts of Eg₁, Eg₂, and Eg₃, respectively, in accordance with an exemplary embodiment of the invention;

FIG. 9D schematically illustrates a top view of the structure as of FIG. 8 of junctions and contacts, in accordance with an exemplary embodiment of the invention;

FIG. 10 illustrates the efficiency of the vertical junction by length and depth, in accordance with an exemplary embodiment of the invention;

FIG. 11 illustrates variability in series resistance in the vertical junction as dependency on light concentration, in accordance with an exemplary embodiment of the invention;

FIG. 12 illustrates expected efficiency of the VMJ cell according to radiation concentration, compared with a high end ordinary (prior art) silicon cell, in accordance with an exemplary embodiment of the invention;

FIG. 13 schematically illustrates the structure of a module composed of VMJ cells with enlarged breakdown of each component up to a single Vertical Junction, in accordance with an exemplary embodiment of the invention;

FIG. 14 schematically illustrates a Silicon-On-Insulator (SOI) substrate structure, in accordance with an exemplary embodiment of the invention;

FIG. 15 schematically illustrates a simulation results for the light path in a junction with pyramids textured surface, in accordance with an exemplary embodiment of the invention;

FIG. 16A schematically illustrates fabrication of vertical high aspect ratio trenches by anisotropic etching technologies, in accordance with an exemplary embodiment of the invention;

FIG. 16B schematically illustrates a structure of a monolithic silicon VMJ cell, in accordance with an exemplary embodiment of the invention;

FIG. 17 illustrates an example of internal structure of neighboring junctions in a vertical multi-junction by directed ion implantation through high aspect ratio trench sidewalls, in accordance with an exemplary embodiment of the invention;

FIG. 18 schematically illustrates V-trenches with partially filled localized contacts, in accordance with an exemplary embodiment of the invention;

FIG. 19 schematically illustrates VMJ after a lift-off process, in accordance with an exemplary embodiment of the invention;

FIG. 20 schematically illustrates two processed wafers prepared for mechanical matching stacking, in accordance with an exemplary embodiment of the invention;

FIG. 21 schematically illustrates a VMJ constructed from the wafers of FIG. 20, in accordance with an exemplary embodiment of the invention;

FIG. 22A schematically illustrates a structure for a VMJ cell with pores arranged in rectangular pattern, in accordance with an exemplary embodiment of the invention;

FIGS. 22B-C schematically illustrates a structure for a VMJ cell with pores arranged in rectangular pattern with attached contacts and current directions therebetween in top and perspective cross-section, respectively, in accordance with an exemplary embodiment of the invention;

FIGS. 23A-B schematically illustrates a top view of a structure for a VMJ cell with pores arranged in hexagonal pattern with attached contacts and current directions and electrical connections therebetween, respectively, in accordance with an exemplary embodiment of the invention;

FIGS. 24A-B schematically illustrates perceptive views formation of contacts and exposure of upper surface, respectively, of VMJ cell with pores arranged in a rectangular pattern, in accordance with an exemplary embodiment of the invention;

FIG. 25 schematically illustrates a top view series connection of junctions of VMJ cell with pores, in accordance with an exemplary embodiment of the invention;

FIG. 26 schematically illustrates a top view of electrical connections of a set of junctions, in accordance with an exemplary embodiment of the invention; and

FIG. 27 schematically illustrates a four-terminal VMJ tandem cell with different number of junctions in each active layer and separate electrical connections for each active layer, in accordance with an exemplary embodiment of the invention;

FIG. 28 outlines a method for monolithic fabrication of vertical junctions PV cells, in accordance with an exemplary embodiment of the invention;

FIG. 29 outlines a method for semi-monolithic fabrication of interleaved vertical junctions PV cells, in accordance with an exemplary embodiment of the invention;

FIG. 30 outlines a method for fabrication of vertical junctions formed in pores, in accordance with an exemplary embodiment of the invention;

FIG. 31 is a simplified schematic illustration of a single vertical junction photovoltaic cell, of which several are included in an example embodiment of the invention;

FIG. 32 is a simplified schematic illustration of two-dimensional VMJ photovoltaic cells, fabricated in an active layer of a Silicon-On-Insulator (SOI) device in accordance with an example embodiment of the invention;

FIG. 33A is a simplified schematic illustration of three-dimensional VMJ photovoltaic cells, fabricated in an active layer of a SOI wafer in accordance with an example embodiment of the invention;

FIG. 33B is a simplified flow chart illustrating a method of manufacturing the example embodiment of FIG. 33A;

FIG. 34 is a simplified graph illustrating efficiency of three-dimensional VMJ cells produced in accordance with an example embodiment of the invention, vs. radiation concentration and pore depth;

FIG. 35 is an image of an array of vertical junction cells produced according to an example embodiment of the invention, mounted on a chip carrier;

FIG. 36 is an image of an experimental setup for characterizing the array of FIG. 35; and

FIG. 37 is a simplified graph illustrating measured and simulated efficiency of VJ cells produced in accordance with an example embodiment of the invention, vs. junction width.

### DESCRIPTION OF EMBODIMENTS OF THE INVENTION

The present invention, in some embodiments thereof, relates to a photovoltaic cell design and, more particularly, but not exclusively, to a monolithic photovoltaic cell design.

As used herein, the term ‘monolithic’ implies, without limiting, that functional units such as semiconductor junction are formed in a single piece of material, optionally disregarding auxiliary components attached to the piece.

As used herein, the term ‘semi-monolithic’ implies, without limiting, attaching (e.g. bonding) two or more monolithic units to form a once-piece apparatus or part thereof, optionally disregarding auxiliary components attached to the units or apparatus.

As used herein, and unless otherwise specified, an intended (designed) radiation incidence angle (also referred to as ‘incident radiation’) is perpendicular to a cell's general surface intended for exposure to the radiation, without precluding or limiting inclined radiation when a cell is exposed to electromagnetic (e.g. solar) radiation.

### General Overview

In an exemplary embodiment of the invention, there is provided a photovoltaic cell which converts sunlight to electricity at a possibly higher efficiency compared to existing cells, and with optionally improved flexibility for integration in modules, one or both of one-sun and concentrating. In some embodiments, a typical concentration is about 400 to about 1000, wherein in some embodiments the concentration is to about 2000. The new cells, in some embodiments, contain many junctions, which are internally connected in series. Such configurations may be called Vertical Multi-Junction (VMJ) or Monolithic

Integrated Modules (MIM) and they are optionally capable of providing very high open circuit voltage, for example, 20-200 volts for Si cells or 50-600 volts for GaAs. In some embodiments a new VMJ cell design is used, based on a monolithic device with PN junctions with substantial near-vertical components (herein “vertical junctions”) with potential significant expected advantages in performance relative to existing VMJ and MIM designs: higher voltage, smaller contact area leading to higher efficiency, better utilization of the solar spectrum, and/or better matching to integration in modules including concentrator modules.

In an exemplary embodiment of the invention, vertical junction high-voltage cells are provided in standard PV panels without concentration and are electrically connected in parallel instead of series, leading to nearly independent operation (e.g., voltage-coupled instead of current-coupled) even under part shading conditions.

In some embodiments, the cells are electrically connected in parallel and in series and wherein, optionally, the largest number of elements consisting of cells or groups connected in series is fewer than six.

In some embodiments, plurality of modules are mounted on a mounting structure, wherein the cells are electrically connected in parallel and in series and wherein, optionally, the largest number of elements consisting of cells or groups connected in series, are fewer than six.

In some embodiments, the cells are electrically connected at least in parallel, and in some embodiments, a plurality of modules are mounted on a mounting structure, wherein the cells are electrically connected in parallel.

a plurality of cells according to claim 1 mounted on a mounting structure, wherein the cells are electrically connected at least in parallel.

In some embodiments, a solar energy receiver comprises a plurality of cells mounted on a mounting structure, wherein the cells are electrically connected in parallel and in series and wherein, optionally, the largest number of elements consisting of cells or groups connected in series is fewer than six.

In an exemplary embodiment of the invention, in concentrating PV applications using the dense-array approach, vertical junction cells can be connected in parallel instead of series. Such an array may be less sensitive to non-uniformities in the incident concentrated flux. This can improve the overall system performance, and possibly permit a less demanding and less expensive optical design. Optionally, by providing a system less sensitive to non-uniformities, homogenizers and other uniformity producing elements may be avoided and/or simplified.

In an exemplary embodiment of the invention, in concentrating PV applications using an array of lens-single cell units, vertical junction cells can be connected in parallel instead of series. Such an array may be less sensitive to partial shading of the lens units in the array, and to effects of misalignment between the lenses in the array. This can improve the overall system performance, and possibly permit a less demanding and less expensive optical and mechanical design. In an exemplary embodiment of the invention, a constructed solar system includes mechanical tracking means (e.g., a motor or other actuator) and optionally a controller for the tracking means.

The conversion efficiency of photovoltaic cells is typically a balance of many influencing factors, including: the effectiveness of absorption of solar photons and their conversion into free electrons; transport and recombination of the free electrons; series resistance within the cell's active material and in the metal conductors collecting the current; optical losses due to shading by the front metal conductors, and electrical losses due to shunt current in the shaded areas. Existing cell designs represent a compromise of these conflicting effects. For example, front metallization should be reduced to minimize shading and shunt current, but excessive reduction will produce significant series resistance.

The new cell design approach presented here in accordance with some embodiments of the invention improves cell performance, in some embodiments thereof, by using a new structure that provides high voltage and low current. An expected result of the new design may be expressed by one or more of reducing the inactive cell area, eliminating front surface shading altogether, reducing series resistance losses, and/or providing an additional degree of freedom for optical vs. electric properties optimization, for example the existing tradeoff between photon absorption, minimizing recombination and reducing electrical resistance. In an exemplary embodiment of the invention, photon absorption is determined by the cell thickness as before, but recombination and electrical resistance are determined by the width of the junction (in a direction parallel to the cell base), which is a separate dimension.

In addition to the performance of a single cell, it may be noted that module-level and system-level losses can also have a significant effect on overall performance. Important effects include series resistance in the external circuit that collects current from the cells, and the effects of non-uniform illumination on different cells in a series-connected module. Optionally, such effects are compensated for and/or reduced using methods described herein.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways. Most of the contemporary commercial PV panels contain arrays of cells connected electrically in series to achieve high voltage (a “string”). When a panel is partly shaded, one or more shaded cells in such a series-connected string can cause the entire string to drop out of the electrical network by activating a bypass diode associated with the string. This can cause significant energy losses in excess of the actual shaded fraction [1]. The availability of high-voltage cells according to some embodiments of the proposed design will enable parallel cell connection instead of series connections, allowing cells to operate nearly independently, and restricting the loss of energy to the shaded area only. In an exemplary embodiment of the invention, unlike existing systems where PV panels are spaced apart to avoid shading, such spacing can be reduced and thereby save space, support structure and/or simplify support design. Optionally, shading of at least 2%, 5%, 10%, 20%, 30% or intermediate percentages are allowed for at least part (e.g., 10%, 20%, 30%, 40%) of the daytime.

The same series connection effect exists in Concentrating PV (CPV) systems based on the dense array design. In this case, the non-uniformity in cell illumination results from the particular design of the optical concentrator as well as from shading by neighboring concentrators. In the CPV case, the potential advantage of the parallel connection of high-voltage cells is not only in performance, but also in reduction or elimination of additional optical components designed to improve uniformity [2], leading to simplification and lower cost of the system. Optionally, homogenizer loss of, for example, 15-22% or 8-12% is avoided.

In conventional semiconductor solar cells the output current of an individual cell increases with the active photovoltaic junction area of the cell, while the voltage across any given cell is nearly fixed, around ⅔ of the semiconductor bandgap, which is typically less than 1 Volt. Therefore, to configure a device having a usable voltage range, individual cells may be connected in series to produce the desired output voltage. However, series connection of cells forces all cells to share the same current. When cells in a series connected string are subject to different incident illumination, the shared current constraint leads to severe degradation of the string's performance.

A method to increase the voltage of a single device is the Monolithic Integrated Module (MIM), which is a single device containing many junctions manufactured monolithically on a single substrate, and electrically connected in series [3].

Unless otherwise specified, designating positions or arrangements (e.g. order of layers) the term ‘top’ refers, according to the context, to the side or direction towards the intended radiation or relative to a reference (e.g. base layer); related terms such as ‘over’, ‘under’ or ‘bottom’ are to be understood accordingly.

In some embodiments, monolithically forming vertical junctions calls for methods for doping sides of nearby adjacent structures which, in some embodiments, are not straightforwardly accessible to conventional fabrication methods.

One exemplary approach is forming trenches in a substrate and doping zones or regions about the sides of the trenches. In some embodiments, trenches with slanted sides (e.g. V-cross-section) are formed allowing access to the sides thereof such as by aiming an ion gun towards the slanted sides from the open side of the trench (e.g. opposite the tip of a V-shape).

Another exemplary approach is forming in a substrate widely spaced trenches (relative to trenches between closely packed adjacent junctions) and doping zones about the sides of the wide trenches, where the wide spacing allows access for doping procedures such as aiming an ion gun. Having two such structures, the junctions are interleaved such that one junction in a structure fits between two junctions in another (complementary) structure.

Yet another exemplary approach is to form pores (holes, cavities) in a substrate to dope the sides of the pores. As the pores are open towards the surface of the substrate they allow access for doping procedures such as by masking. In some embodiments, the pores are sufficiently wide (e.g. macro-pores) allowing access to the sides thereof such as by aiming an ion gun towards the sides.

In some embodiments, combinations of the described approaches, optionally with other approaches, may be used to form monolithic vertical junctions.

In some embodiments, and according to an approach above, an exemplary apparatus is a monolithic cell comprising a plurality of vertical junctions separated by generally vertical trenches doped at the sides thereof. Optionally, the trenches are slanted with wider externally facing dimension than the internally facing dimension, where, optionally, the sides are electrically responsive to electromagnetic impinging on the sides.

In some embodiments, and according to another approach above, an exemplary apparatus is a monolithic cell comprising a plurality of interleaved complementary junctions. In some embodiments, the cell comprises two (or more) structures with a plurality of spaced junction attached (e.g. bonded) to each other so that a junction of one structure fits between two junctions of another structure.

In some embodiments and according to yet another approach above, an exemplary apparatus is a monolithic cell comprising a plurality of junctions in formed about sides of pores (holes, cavities) formed in a substrate.

In some embodiments, electric connection between the junctions in the cells such as described above is facilitated by electric conductor disposed in the trenches, or between the interleaved junctions or in the pores, respectively.

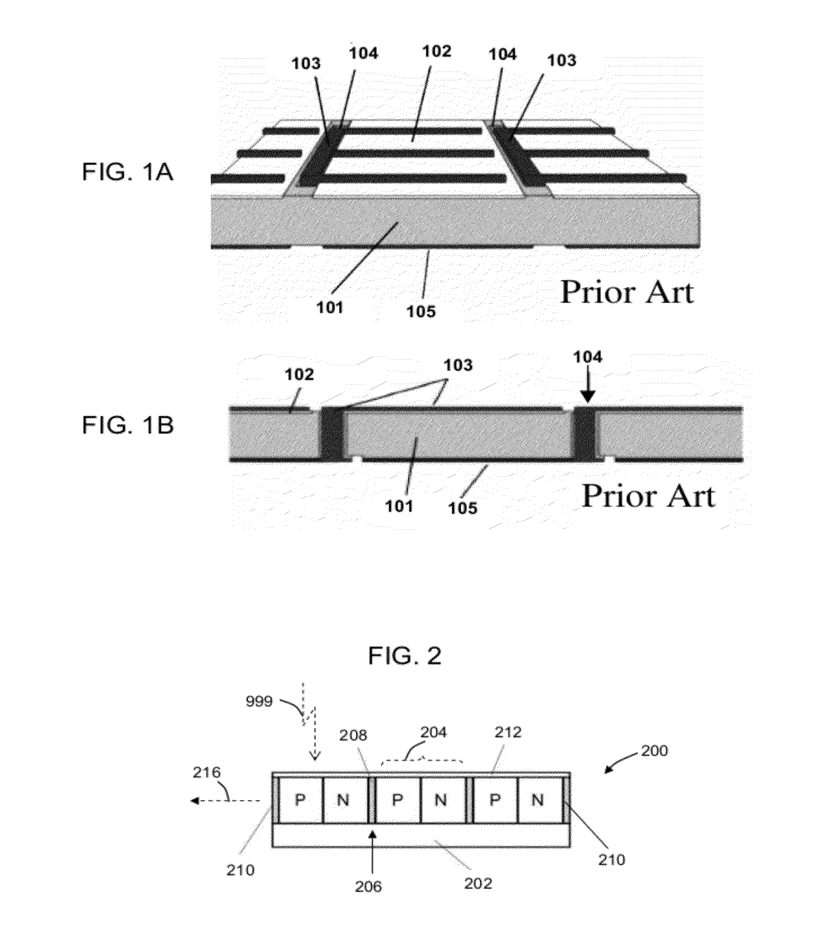

FIG. 1A-B schematically illustrate a top view and cross section views, respectively, of a typical horizontal junction MIM according to [1].

The device is based on a standard horizontal P-N junction (stacked horizontal layers) of emitter (102) on a silicon wafer (101). The division into multiple junctions is achieved by removing some wafer material, creating trenches (104) reaching from the cells front (top) surface to the back surface, leaving separate unit sub-cells. The trenches are then filled with metal to create the series connection between the back electrode (105) on one junction and the top busbar of the neighboring junction (103).

Since the early 1980's efforts have been reported to design and fabricate various types of MIM cells by a number of technologies and in different materials: thin-film, either amorphous [4] polycrystalline, or epitaxial [5] silicon; and gallium arsenide [6]. The crystalline silicon monolithic [3] technology is another technology.

The efficiencies obtained so far are much lower than state of the art technology for individual cells. This may be due to one or more of the following reasons: poor isolation between contiguous solar cells, high series resistance due to interconnects. In an exemplary embodiment of the invention, poor isolation is solved by avoiding the provision of contact areas between cells that need to be isolated. Optionally or alternatively, series resistance is reduced by the electrical conduction path through the metal interconnect being relatively short (e.g., only the thickness of the metal layer). In an exemplary embodiment of the invention, a single photovoltaic device with output voltages not being limited by the energy-band gap of the device's semiconductor material is provided, by connection in series of multiple junctions within the device.

A proposed structure of a high-voltage MIM device, in accordance with one embodiment of the invention is based on P-N junctions with vertical orientation, made from side-by-side vertical layers rather than stacked horizontal layers of the prior art such as of FIG. 1.

The basic scheme of vertical junctions as described herein has several non-limiting variants, including also semi-monolithic constructions and multi-tier (stacked layers) constructions as described below.

The geometry of a Vertical Multi-Junction (VMJ), in accordance with some embodiments of the invention, is shown schematically in FIG. 2 as described below.

FIG. 2 schematically illustrates a structure 200 of a Vertical Multi-Junction (Lateral Junction MIM, L-MIM), in accordance with an exemplary embodiment of the invention.

Structure 200 comprises a substrate 202 on which junctions 204 are formed between trenches (grooves) 206 which are filled with metal 208 for electrical connection between junctions 204. Junctions 204 are illustrated as N-P pairs, one of which is indicated by dashed bracket 204. Junctions 204 represent a plurality of junctions, and structure 200 is also referred to as a ‘cell’. Structure or cell 200 comprises at the sides thereof electrical contacts 210 for electrical connection of a plurality of cells 200. Typically the junctions are covered by a top window and a passivation layer or layers 212. Dashed arrow 999 indicates general direction of electromagnetic radiation impinging on the top of cell 200 and dashed arrow 216 indicates general direction of electric current flow when the junction is activated by radiation and a load (or short) is connected between contacts 210.

The intended incident solar radiation enters generally parallel to the junction interface (from the top in FIG. 2, see arrow 999), while the electrical current flows, perpendicular to the junction interface (horizontally in FIG. 2). Thin vertical metal lines create a series connection of adjacent junctions. The total current of the VMJ equals approximately the current of a single unit junction, while the voltage is the sum of the individual junctions. The output power per unit area can be at least the same as for a conventional cell, with potential improvements, inter alia, due to potential differences in conversion efficiency that will be discussed below.

Optionally, the VMJ structure is applied to any semiconductor material sets that are known in the photovoltaic cell industry, such as silicon (single crystal, polycrystalline, amorphous), germanium, gallium arsenide, cadmium telluride, Copper indium gallium selenide, and other known cell materials, as well as other materials and their combinations and alloys that may be identified in the future as suitable for photovoltaic cells.

One difference between the above structures (e.g. structure 200) and other proposed “edge-illuminated cells” or “vertical multi-junction cells” [7] is that the above structure is monolithic, while in the art the suggested method to produce devices such as in [7] was to manufacture conventional P-N junctions on individual wafers; bond them side by side; and then slice in a perpendicular plane to create a layer containing a series of lateral junctions [8]. A potential advantage of some embodiments of the invention is that the manufacturing process can be less complex and/or with fewer device-level manipulation steps. Another difference is that manufacture in some embodiments of the invention need not be from silicon cells (e.g. be from III-V semiconductor materials, such as GaAs) and thus possibly yield greater efficiencies.

In an exemplary embodiment of the invention, the proposed designs are applied to thin-film cells, where the amount of material can be considerably reduced (e.g., by a factor of 2, 5, 10, 15 or intermediate or greater factors) relative to single-crystal cells. In an exemplary embodiment of the invention, the methods and apparatus described herein are used as part of one-sun applications and/or as part of as concentrator systems (e.g., with a solar concentrator), and/or using simple single junction technology (e.g., all junctions the same and in one layer) and/or multi-type junction cells (e.g., multiple layers and/or junction types) and/or high-performance systems.

In an exemplary embodiment of the invention, it is suggested to manufacture the series of vertical junctions in a single layer as a monolithic device on a single wafer, with no assembly, bonding and/or re-cutting of separate wafers. In an exemplary embodiment of the invention, the entire cell including all junctions and embedded metal lines is created by subsequent processing steps on the same wafer or substrate.

Unless otherwise specified, the terms ‘boundary’ (e.g. inner boundary) or ‘interface’ refer to an interface between two different material regions such as N-P regions or such as about the N-P depletion zone.

As used herein, vertical junctions include also junctions whose inner boundary between materials is not strictly vertical. For example, the junction can be at an angle of up to about 30 degrees with respect to the intended radiation incidence angle, or the junction may include one or more horizontal or near horizontal components, for example, of up to about 30%, 50% or 70% in area such that the junctions with at least 30% of said boundary being within 30 degrees of a design radiation incidence angle A potential particular benefit of using vertical junctions, as utilized in some embodiments of the invention, is that the junction materials can be thick enough to absorb radiation, while still being mostly or completely (e.g. about 80% or 90% or 95% or intermediate or greater values) in the field region of the junction and allowing direct radiation impinging on the junction materials.

In an exemplary embodiment of the invention, the above percentages of material are within a diffusion length of the junction, optionally, within less than a diffusion length, for example, 30%, 50%, 70 or 90% of a diffusion length, or intermediate percentages. Alternatively, the above percentages are within more than a diffusion length, for example, 110%, 120% of a diffusion length.

In an exemplary embodiment of the invention, the cell junctions are thick enough to absorb, for example, at least 70%, 80%, 90% of impinging radiation at wavelengths that significantly interact with the materials used in the junctions. Optionally, the distance of travel required by generated carriers is reduced as compared to stacked cells, for example, being 50%, 30%, 20% or less, thereof, on the average.

In some embodiments the different materials of a junction have different volumes and/or widths, for example, having a ratio of 1:2, 1:4, 1:10, 1:20 or intermediate or greater ratios of width or volume between the two materials (e.g., n and p doped silicon).

Following are potential advantages and/or features of the Monolithic VMJ approach relative to the previous designs, one or more of which are optionally provided in accordance with exemplary embodiments of the invention:

Minimization of the metal contacts area: metal layers for series connection are optionally perpendicular to the front face of the cell, thus their width can be minimized, limited only by manufacturing capabilities. As noted with respect to the junction boundary, in some embodiments, the angle is near perpendicular, for example, within 30 or 20 or 10 (or less) degrees of the perpendicular, for example, matching crystal planes, for example parallel to the 111 plane in a silicon wafer. Optionally, the width (aspect) is on the order of microns, for example, 1 micron or <2 microns.

Metal fingers on the top surface, needed in conventional cells and in existing MIM designs, are possibly unnecessary and optionally not provided. Hence, shading and shunt currents in the dark areas under fingers and busbars can be eliminated. Moreover the metal lines may be recessed below the top surface and/or hidden in a direction away from the surface. Optionally, such designs lead to nearly zero loss of active area (e.g., less than 5%, 2%, 1%) of the total exposed area of the front face of the cell.

Additional flexibility for optimization: the proposed geometry decouples the optical and electronic effects into orthogonal directions. The cell thickness can be optimized for solar radiation absorption, while the unit junction width is optimized for carrier collection (diffusion length, electric field, etc.).

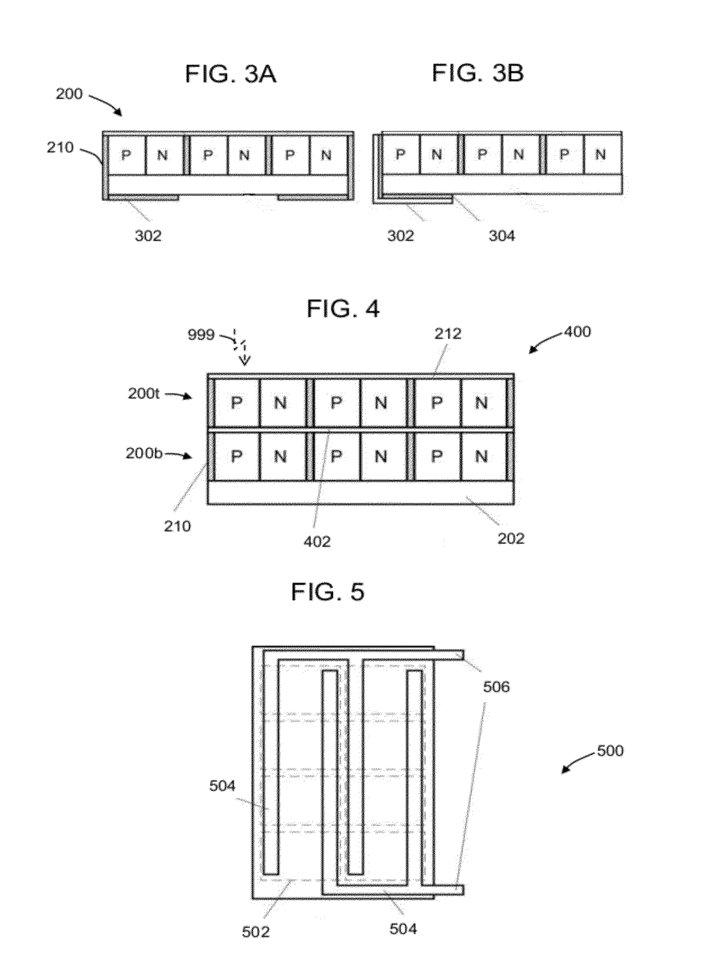

Edge or back contacts: edge contacts can be implemented with substantially no added shading (See for example, FIG. 2), optionally having edge contacts with a thickness and/or other geometry similar to that, or within a factor of, for example, 1.1, 2, or 4 of thickness of the lines between junctions. Back contacts for streamlined mounting on modules can be added, with optionally very little change in cell dimensions, as shown, for example, in FIG. 3.

With reference to FIG. 2, FIG. 3A-B schematically illustrate VMJ cells 200 with integrated and soldered back contacts 302, respectively, in accordance with an exemplary embodiment of the invention.

In FIG. 3A, back contact 302 is an extension or folding of end contact 210, while in FIG. 3B back contact 302 is soldered to cell 200 by a solder layer 304.

Bifacial cells: the proposed design supports, in some embodiments, effective bifacial (double sided) illumination for increased power, due to the junction symmetry and absence of front and back contacts. Optionally, the cells are formed on a transparent substrate (e.g., glass or fused silica). In an alternative design, the cells are strong enough to support themselves and have a passivation layer (e.g. layer 212 of FIG. 2), for example, on either or both faces

Concentrating PV applications: the Monolithic VMJ may be a universal solution for CPV in that it need not necessarily require redesign for different concentrators. In contrast to conventional cells and MIM, the contacts metallization does not depend on the incident flux concentration, since the current flows across, not along the metallization lines (e.g. arrow 216 with respect to metallization lines 208 of FIG. 2).

Multi-spectral cells: In an exemplary embodiment of the invention, multiple junctions are provided, for example as layers of junctions that may use different photovoltaic materials in each layer. Optionally, the use of different materials supports coverage of different parts of the spectrum for better use of the solar spectrum and increased overall conversion efficiency.

FIG. 4 schematically illustrates a stacked VMJ 400, in accordance with an exemplary embodiment of the invention. A stacked structure may or is also referred to as multi-tier or multi-layer or multi-junction structure.

Structure 400 illustrates two layers similar to structure 200, illustrated as 200t and 200b (for ‘top’ and ‘bottom’, respectively). Structure 200t is typically covered with passivation and/or window 212. Structures 200t and 200b are separated by an electrical insulation layer 402 which is transparent to the bandwidth of electromagnetic radiation (e.g. schematically illustrated by arrow 214) which correspond to the absorption bandgap of the junctions of structure 200b.

Structures 200t and 200b represent any number of stacked layers separated by insulation layer such as layer 402 to allow radiation that was not absorbed by upper layers to reach lower layers. Optionally the junctions are not aligned over each other and/or the number of junction is different in each layer and/or the widths of the junctions are different within and/or between each layer.

In some embodiments, each layer forms a separate electrical circuit, each with two contacts (e.g. 210), leading to a four-terminal cell that can operate without current matching between the layers. As optionally the number of junctions and width of an individual junction in each layer can be different, such difference is used, for example, to compensate for junctions of different materials producing different voltages. The numbers of junctions in each layer is optionally chosen such that the overall voltages produced by each layer are identical (or nearly so, for example, within 5% or 1%), and in this case the end terminals can be common to all layers (two-terminal cell, e.g. where contacts such as 210 at each side of structures 200 are shortened).

The range of cell design parameters (e.g., junctions and/or subcell thickness and height, dopant concentration) that lead to optimal performance are different for each semiconductor material that is chosen for the cell. For example, a junction width of around 20-100 microns and a depth of 25-100 microns for crystalline silicon may be provided. For GaAs cells and for similar materials of the III-V family an exemplary design is junction width 5-50 micron, depth 1-5 microns.

Standard (e.g. prior art) PV cells usually have back and front electrodes, so that assembling cells into modules then requires an additional electrical element and an additional processing step to connect the front electrode to the back plane of the module.

In an exemplary embodiment of the invention, the cells have two or more back contacts, and assembly (optionally automatic) can be done by simply placing the cells next to each other on a suitable substrate and soldering and/or otherwise connected, optionally in a manner providing good thermal flow. The Monolithic VMJ cells are optionally manufactured with two back contacts (e.g., FIG. 3A) with possibly no compromise of performance or manufacturing cost.

Since each VMJ cell produces high voltage (e.g., 12V, 100V, 110V, 220V, 500V or intermediate or greater voltages), it is possible to produce a module having reasonably high voltage with all the cells connected in parallel. For example, a VMJ can produce 100V or more by itself, so there is no need for series connections before input into an inverter. This type of module can be very robust under variable incident flux, for example when part of the module area is shaded by a neighboring panel or by a tree or clouds or dirt. The same approach can be applied to concentrating dense array PV modules, where incident flux may vary depending on the concentration optics.

FIG. 5 schematically illustrates a substrate layout 500 for a module with parallel VMJ cells, in accordance with an exemplary embodiment of the invention.

The dashed rectangles 502 illustrate the position of VMJ cells with back contacts. The cells are placed on the module and soldered directly (or coupled by contact or other method) to busbars 504 printed on the module and the module terminates with two contacts 506. The illustrated cells positions and busbars represent any number of position and busbars according to a module layout design.

It is also possible to have mixed series and parallel arrangements of the cells in a large cell array, for example to connect a small group of cells (<5) in series, and connect all groups in parallel. In prior art cell arrays, usually large groups of cells in a panel (>10, typically >18 for standard silicon cell panels) are connected in series, and then many panels are further connected in series, to achieve high voltage into the inverter such as 200V or 500V. Using the proposed VMJ cells only a small number of cells (1-5) connected in series can achieve the same voltage to the inverter, and many such groups can be connected in parallel to each other.

Alternatively, a group of many VMJ cells can be connected in parallel, and a small number of groups (<5) is then connected in series to achieve the desired voltage input to the inverter.

In modules and receivers containing many cells it is customary to install protection measures such as bypass diodes across cells or groups of cells for protection of the cells from adverse currents or reverse voltage, which may occur when some cells are shaded. In parallel configuration such as layout 500 of FIG. 5 these protection measures may be unnecessary.

Many concentrating PV systems under development are based on dense-array modules. Such designs typically rely on many small PV cells of existing III-V technology, connected electrically in series. The series connection is needed in order to achieve a reasonable exit voltage and to minimize the current, the same design approach that is used in one-sun modules. The series connection design leads to a severe requirement of incident flux uniformity: if one of the cells in the array generates a lower current, then the performance of the entire module will be compromised. In order to circumvent this difficulty, an additional optical element (often called homogenizer, kaleidoscope, or waveguide) is inserted between the concentrator and the module [9]. This element is a cavity with a rectangular cross section and reflective internal walls, with the radiation entering in one aperture and the module installed at the opposite aperture. When the homogenizer length is properly chosen considering its aperture size and angular range of the incident radiation, it can effectively redistribute and homogenize the flux distribution incident on the module. However, the reflections at the homogenizer walls involve power loss, which can reach 5-15% for practical designs and reflector materials [2].

In an exemplary embodiment of the invention, there is provided an alternative module design with a parallel electrical connection of the cells. Each cell can then produce a different current without much impact on the other cells. The flux uniformity requirements, and the need to install a homogenizer, are then eliminated. This can allow a simpler and/or lower-cost optical system and can eliminate or reduce the losses associated with a homogenizer.

Another concern in some CPV applications is the high current per unit area of the cell, leading to high losses due to series resistance. This forces cell designers to compromises such as increasing the area fraction dedicated to front surface electrical conductors, or reducing the overall size of the cells down to approximately 1 mm² [10]. The first method increases the area fraction that is shaded from incident sunlight and thus reduces cell efficiency. The second method increases the effort and cost involved in handling and mounting many small cells into the module instead of a single larger cell. A new cell design such as described herein can, in some embodiments thereof, provide high voltage with a reasonable unit size for module assembly, for example around 100 mm² (optionally the same size as existing CPV cells). In an exemplary embodiment of the invention, the inactive area due to metallic conductors is kept to an absolute minimum that does not require redesign for different values of the concentration level and cell current.

In an exemplary embodiment of the invention, a standard PV panel without concentration uses VMJ cells which are electrically connected in parallel instead of series, leading to nearly independent operation (voltage-coupled instead of current-coupled) even under part shading conditions. This may lead to higher overall energy collection of these advanced PV panels and to improved competitiveness.

In an exemplary embodiment of the invention, a concentrating PV application uses the dense-array approach and VMJ cells are connected in parallel instead of series. Such an array may be less sensitive to non-uniformities in the incident concentrated flux. This possibly improves the overall CPV system performance and/or permits a less demanding and/or less expensive optical design. Optionally, the inventive arrays are used in any existing or future CPV dense array systems substantially independently of size and/or concentration technique.

In an exemplary embodiment of the invention, the above designs are used for non-grid connected applications, for example, as power sources for autonomous portable devices and for MEMS devices [11]. In these cases only small amounts of power (small cell area) may be needed, but the voltage must be high enough to power the electronics. A cell that will produce the required voltage without the need for an up-converter is optionally used instead of a system with an upconverter and/or unstable voltage.

In an exemplary embodiment of the invention, the optimal geometrical and/or material parameters for a particular design are found using a simulation program. Optionally, the three-dimensional Synopsys TCAD Sentaurus (Synopsys, Inc.) device simulator that solves the fully coupled continuity and Poisson equations under solar illumination, or other software, such as Silvaco (SILVACO, Inc.), Comsole (COMSOL AB), with such capability, is used.

It is noted that simulation tools, such as cited above and below, generally provide realistic results and/or sufficiently close approximations of actually fabricated devices; thus reference to realistic examples or performances are based on simulations and/or prior experience and/or wisdom of the art.

In an exemplary embodiment of the invention, a simulation is used to first find the required depth and width of the junctions, which are typically different from conventional horizontal junctions where the photo generated carrier diffusion is in the same direction as the junction electric field. In an exemplary embodiment of the invention, cell dimensions are selected so that the carriers will be swept to the vertical contacts before reaching the back of the device. Optionally, the design makes use of the fact that typically in P-N junctions the current drift term is much larger then the diffusion. Optionally, the design is selected so that all the excess carrier pairs which arrive at the ohmic contacts recombine and in principle should not contribute to the external current. Optionally or alternatively, the unit cells geometry is designed so that the carriers are separated by the junction electric field.

It is noted that some of the potential advantages of some embodiments of the invention are expressed only at the module and system level, for example, reduced sensitivity to part shading and flux non-uniformity, elimination of the homogenizer in CPV and/or reduced series resistance in external conductors due to lower current. Other potential advantages are at the cell level, for example, higher active area and reduced series resistance loss in the cell.

In an exemplary embodiment of the invention, the fabrication method used is an existing monolithic fabrication process using off-the-shelf Si (e.g., single crystal, polycrystalline or amorphous) or MN technologies that are adapted to the VMJ geometry. Optionally, the doping profile and contact implementation are optimized once the approximate geometry has been identified (e.g., based on the simulations). Optionally, the procedures for these processes in both GaAs and Si as described, for example, in [12], are used. Various design alternatives may be provided, based on the particular usage and its optimization, for example.

### Exemplary Proposed Architecture

Following below are proposals to construct a novel photovoltaic cell architecture converting sunlight into electricity at significantly higher efficiency relative to conventional cells, using descriptions provided herein as exemplary embodiments of the invention. Examples are provided for multi-layer (multi-tier, stacked) architecture as non-limiting examples and an architecture of any number of layers, including single layer (see also further below) may be derived, mutatis mutandis, therefrom.

The proposed device comprises series-connected vertical PN junctions in a monolithic Vertical Multi-Junction (VMJ) array within a single cell. VMJ cells can offer significant advantages over conventional cells, such as: higher voltage, allowing parallel cell connections with significant reduction in mismatch losses and reduction in need for secondary optics; smaller inactive area loss; lower series resistance loss; decoupling of optical and electronic effects into orthogonal dimensions, and/or allowing better optimization of junction dimensions. The theoretical feasibility of the monolithic VMJ cell concept in silicon is validated, using detailed physical simulations with representation of realistic fabrication methods. Results show that VMJ cells can operate well under concentration of several thousands, compared to only a few hundred for conventional Si cells. The model predicts VMJ cell efficiency of up to about 34%, significantly above the highest reported efficiency for Si cells. Simulation of a module of VMJ cells connected in parallel under extremely non-uniform illumination has validated very low mismatch loss, confirming the additional advantage at the module and system level.

Due to short diffusion length in III-V materials such as GaAs, the junction width will sometimes be very small (about 3 microns), possibly leading to very high voltage in cells of reasonable size: e.g. a 1 cm cell can produce about 3,000 V. This high voltage may be difficult to insulate and/or otherwise inconvenient from practical considerations. An exemplary embodiment that may overcome these issues is to have a mix of series-parallel connections within a cell. For example: have a VMJ set connected in series over 1-2 mm of the cell length (e.g., each set producing about 200-800V such as 300-600V); then connect all sets in parallel by a connection that runs sideways to the edge of the cell. The side edge metal strips then become the cell terminals for external connections.

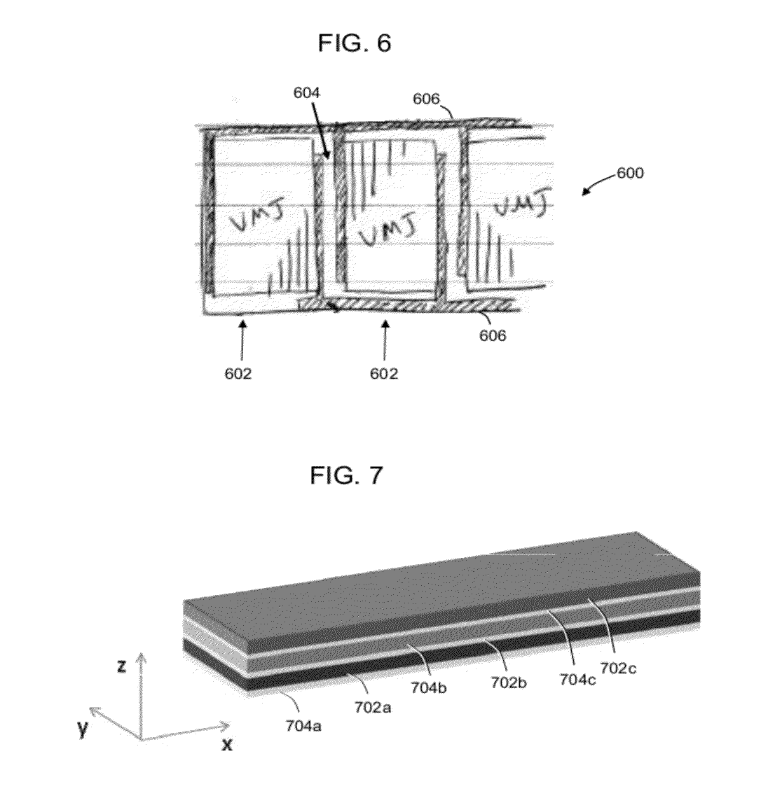

FIG. 6 schematically illustrates a VMJ cell construction 600 with mixed series and parallel connections, comprising a plurality of VJ arrays (subcells) 602 internally connected in series and separated by wide trenches 604 (e.g. relative to inter-junction trenches), in accordance with an exemplary embodiment of the invention. The connection between the VJ arrays is a parallel connection by metallizations 606. The illustrated VMJ cell 600 represents or comprises any number of VJ arrays 602.

FIG. 7 schematically illustrates groundwork structure (bulk) 700 for a design for a VMJ tandem multi-terminal cell of a plurality of different materials, in accordance with an exemplary embodiment of the invention.

Structure 700 comprises three layers 702a, 702b and 702c made of semiconductor (e.g. P-type) with different band gaps (e.g. different doping and/or doping concentration), representing any number of such semiconductors layers. Layer 702c is illustrated as a top layer towards the incident electromagnetic radiation. For later references, the bandgap of the 702 layers are tagged as Eg₁, Eg₂, and Eg₃ respective to layers 702a, 702b and 702c.

Layers 702 are separated by electrical insulating layers 704 wherein layers 704 are transparent for radiation that passes though upper layers. In some embodiments, bottom layer 704a is a substrate and/or base and/or handle for structure 700.

In some embodiments, in order to produce a multi-terminal device of some types of designs, each semiconductor layer should have different junctions and contacts. This can be done, for example, by creating the junctions by doping through the walls of pores or up side down pyramids or DRIE anisotropic etch, at different depth (in order to reach the desired semiconductor layer).

In some embodiments, each pore will be filled with metal up to the top of its layer. The contacts will be inserted into each pour in such a way that they will contact the desired layer only.

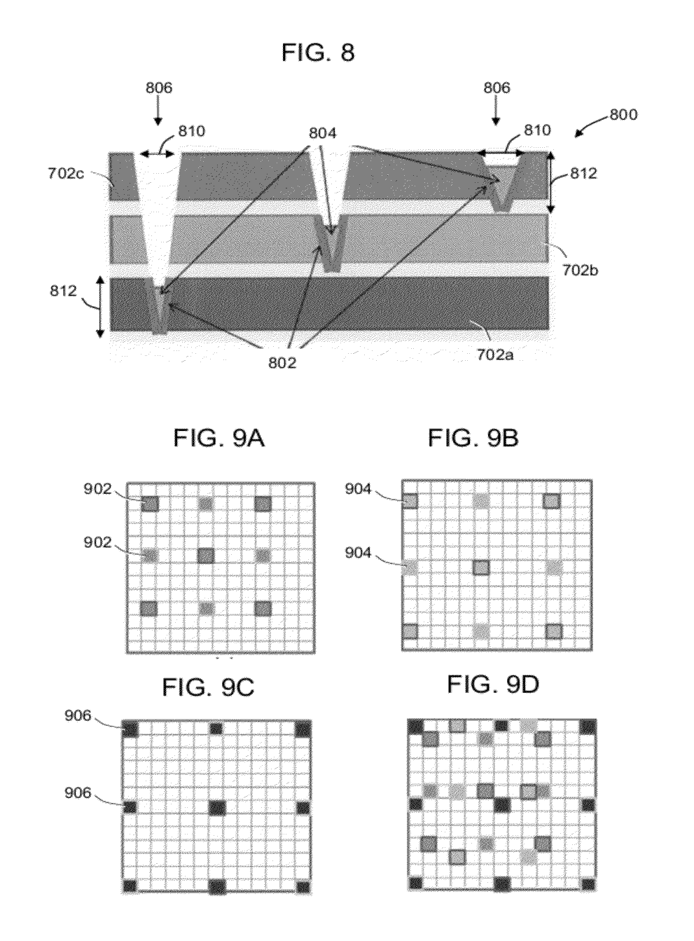

FIG. 8 schematically illustrates a side view of the structure 800 of the junctions and contacts at the various depths formed in the groundwork (bulk) 700 of FIG. 7, in accordance with an exemplary embodiment of the invention.

In some embodiments, bulk 700 is processed to form trenches 806. In some embodiments, trenches 806 are triangular (V-groove, as illustrated), and in some embodiments trenches 806 have other forms (cross sections). In some embodiments, trenches with slanted edges (e.g. about 15-30 or more degrees) allow doping such as by ion gun aimed about the trench side inner surface.

In some noteworthy embodiments, the width 810 is much smaller than the depth 812 of a trench 806, where in some embodiments the ratio of a depth 812 to width 810 of trench 806 is more than about 10 such as about 40, or optionally more than 100 such as about 400.

In some embodiments, to form junctions (e.g. junctions 204 of FIG. 2), trenches 806 are doped with impurities about the sides 802 thereof and in some embodiments, electric conductor 804 (e.g. metal alloy) is deposited in trenches 806, allowing current path between the junctions. In some embodiments, the sides of the trenches are N-doped and P-doped (with different doping concentration relative to the bulk). Alternatively, in some embodiments, each other (alternating) trench is doped with about the same or about the same N-doping or P-doping (or optionally with different N-doping or P-doping).

In some embodiments, the deep yet narrow trenches reduce the portion of inactive area (that do not respond to radiation) of the cell's junctions whereas the conductor provides effective electric contact between the junctions.

In some embodiments, unless otherwise specified, deep trenches imply trenches that extend throughout the material in which the junctions are formed so that adjacent junctions are separated from each other. Likewise, in some embodiments, unless otherwise specified, depth to width ratio of trenches implies that the depth extends throughout the material in which the junctions are formed.

In some embodiments, the locations of each of the individual layer contacts can be determined by optimizations based on each layer's carrier diffusion length. In a process of optimization each layer is divided into square regions. In the center of each region a P+ contact is formed and the N+ contacts are placed in the middle of the region borders. The size of each region can be determined by the layer's diffusion length.

After the design of each layer is made the designs are put together with a slight shift for final arrangement.

FIG. 9A-C schematically illustrate top views of structure 800 of FIG. 8 of junctions and contacts of Eg1 902, Eg2 904 and Eg3 906, respectively, in accordance with an exemplary embodiment of the invention. The differently shaded boundaries depict different doping in the trenches of the respective layers.

FIG. 9D schematically illustrates a top view of structure 800 of FIG. 8 of junctions and contacts, in accordance with an exemplary embodiment of the invention, as a shifted combination of FIG. 9A-C.

In some embodiments, in order to shorten the path for each charge carrier, hexagonal (or other shapes) is used in the optimization process.

In some embodiments, the design described above allows to optimize the distance between each layer's contacts separately.

In some embodiments, when a peel-off process (see below) is practiced the cells layers may be fabricated to arrange the layers such that Eg1>Eg2>Eg3 (see FIG. 7-8) and the Eg1 layer will be closest to the radiation to reduce shading effect, optionally practically eliminating the shading effect when V-trenches (V-grooves) are used.

In some embodiments, in order to contact the conductors in the layers such as to a bus line, a passivation and/or isolation layer should be disposed on the structure (e.g. structure 700) over the trenches walls which may add to the overall resistance; however, using small distances between the trenches such as with III-V material the added resistance, in some embodiments, is negligible and has no significant detrimental effect.

### Exemplary Performance

Some examples of the simulated performance of photovoltaic device based on vertical PN junctions connected monolithically in series (Vertical Multi-Junction, VMJ) are described below.

The simulation of the vertical junction and the cell containing a monolithic array of vertical junctions was implemented with the Synopsis TCAD Sentaurus Structure Editor and Device Simulator.

Assisted by the simulation, the effect of many parameters on the cell was examined, among these: electron-hole lifetime, P-type/N-type base, and various dopings, duration and doping of the P+, N+ regions.

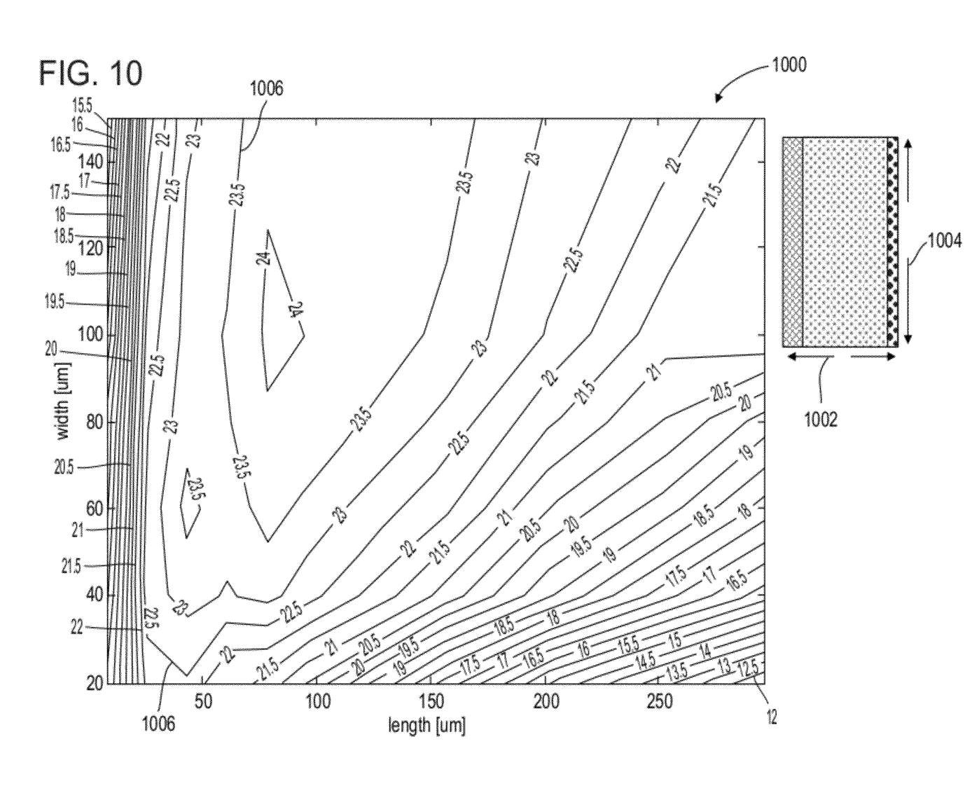

FIG. 10 illustrates in a chart 1000 a realistic simulated example of efficiency of the vertical junction by length 1002 and depth 1004 (from a side view such in FIG. 8), in accordance with an exemplary embodiment of the invention. The vertical axis of chart 1000 is the width in μm and the horizontal axis is the length in μm and the curves 1006 depicts efficiency in percents.

Chart 1000 was generated (simulated) using depth to width ratio (trench aspect ratio) of 1:40 in the shaded area and taking into account recombination processes on the upper and lower surface S.R.=100 cm/sec, and thousandth of second lifetimes. The software enables not only to identify the optimal values of the design parameters, but also to identify physical mechanisms responsible for the drop in efficiency at non-optimal points.

Series resistance in the vertical junction is created through contribution of several factors, the principal being formed by the passage of charge carriers in the cell body (bulk resistance) perpendicular to the junction surface, while in the ordinary horizontal junction cell the principal series resistance stems from resistance to passage of charge carriers parallel to the junction surface (sheet resistance). It was found that this difference has great significance for the performance of the two cell types. The resistance of the body varies with the strength of the illumination (concentration) through a mechanism known as photoconductivity, so that resistance drops when the light concentration rises. In the ordinary horizontal junction (prior art), the contribution of the body resistance to the overall resistance is small and therefore this manifestation does not cause change in the overall series resistance in the junction.

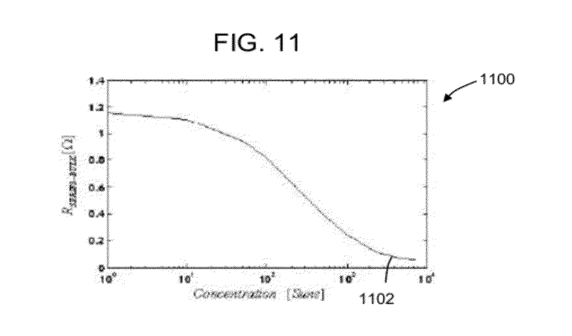

FIG. 11 illustrates in a chart 1100 the variability 1102 in series resistance in the vertical junction as dependency on light concentration, in accordance with an exemplary embodiment of the invention. The vertical axis of chart 1100 is the bulk series resistance in Ohm and the horizontal axis is the radiation concentration in Suns.

The behavior found for the series resistance of the VMJ cell leads to a significant increase in performance of the cell under high concentration.

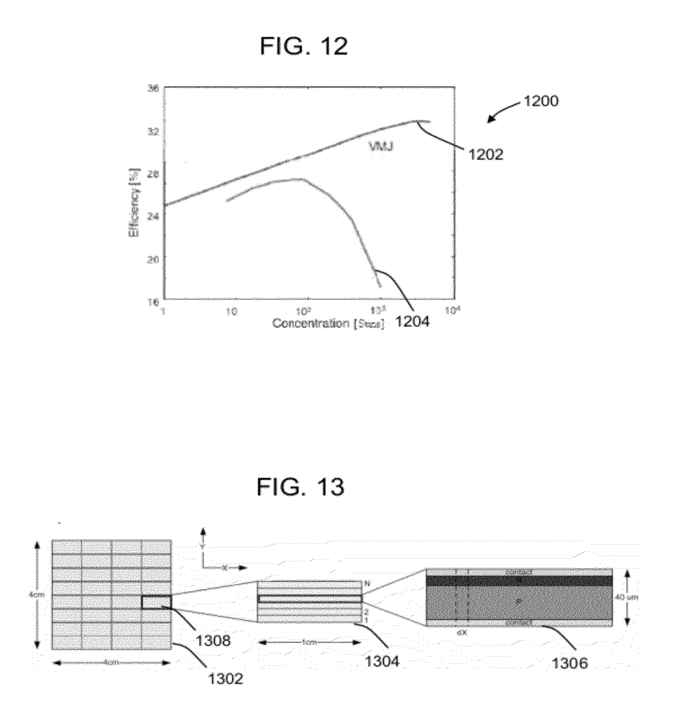

FIG. 12 illustrates in a chart 1200 the expected efficiency of the VMJ cell 1202 according to radiation concentration, compared with a high end ordinary (prior art) silicon cell 1204, in accordance with an exemplary embodiment of the invention.

The vertical axis is the efficiency in percents and horizontal axis is the radiation concentration in Suns.

The ordinary cell with the horizontal junction already begins to show a drop in efficiency at a concentration of several hundred suns, since the increase of current in the cell amplifies the losses stemming from series resistance. On the other hand, the maximum efficiency of the cell with vertical junction is achieved at a concentration of 3,000-4,000 suns, which is substantially higher than that of the ordinary cell, since the series resistance is lower and continues to drop with the rise in concentration. This performance limitation at high concentrations is also manifested in the Tandem III-V cells which are the contemporary leaders in the concentrated radiation sphere.

The expected maximum efficiency of the VMJ silicon cell according to the simulation reaches over 30% and approaches the efficiency range of the Tandem III-V cells.

One of the problems in connecting several photovoltaic cells into a complete module is the problem of adjusting the current and voltage while the cells are non-uniformly illuminated. It may be seen that while the incompatibility of voltages in a parallel connection has relatively little effect, incompatibility of currents in the customary serial connection bears a substantial significance on system performance.

It was found that for a module composed of monolithic VMJ cells, where each cell contains N junctions (see FIG. 13) there is an optimal number of junctions within a single cell, subject to the distribution of illumination of the cell.

The efficiency of the module was calculated for nonuniform illumination by Gaussian distribution for an average concentration of 10.9 (maximum 50) and 1.9 (maximum 10).

FIG. 13 schematically illustrates the structure of a module 1302, with enlarged breakdown to 1304 of each component 1308 up to a VJM 1306.

Also, losses stemming from non-homogeneity of illumination (mismatch loss) were calculated. For two distributions of illumination losses of 4% and 11.5% were obtained. For comparison purposes, losses in a module composed of standard cells connected in series under identical illumination distribution would be about 85%, and therefore this module will require a long homogenizer. The significance of these results is that it is possible to substantially reduce the losses of homogenizer devices in concentration systems (usually about 10%) because the sensitivity of the VMJ module to non-uniformity of radiation will be substantially lower in relation to a module based on ordinary prior art cells.

In some embodiments, for a typical parabolic dish concentrator with a homogenizer with reflectivity of 90%, the a good design for a module with standard cells is a homogenizer of length of about 0.6 times the module size, leading to minimal loss of 9% due to homogenizer absorption and module mismatch. In some cases, other lengths of the homogenizer would incur higher loss. The same system with a module of VMJ cells and without a homogenizer at all would, in some embodiments, incur a mismatch loss of only about 2%.

### Exemplary Fabrication Approaches

Some non-limiting examples for fabrication of vertical multi-junction (VMJ) photovoltaic (PV) devices (cells), and particularly some examples of monolithic fabrications, are outlined below.

Generally, the fabrication can be implemented using various materials, for example silicon (Si), materials such as gallium arsenide (GaAs), and other photovoltaic materials. An example for materials may be an epitaxial structure which includes a group of thin layers designed for reflecting light, and active layer, deposited on a Semi-insulating (SI) GaAs substrate.

### Monolithic Fabrication

In some embodiments, the starting material is an insulating and diffusive light reflecting substrate, with an active semiconductor layer superposed on the substrate.

FIG. 14 schematically illustrates a Silicon-On-Insulator (SOI) substrate structure, in accordance with an exemplary embodiment of the invention. A top layer of an active layer 1402 (bulk) is used for fabricating the junctions which is optionally disposed over an insulation layer 1404. Optionally, layer 1404 is made of SiO₂, serving as insulating and reflective material (because of the difference in refractive index between the SiO₂ and the active layer). In some embodiments, a lower or bottom layer 1406 serves as a handle layer for mechanically holding the device, optionally with back contacts on top or below layer 1406 (see, for example, FIG. 3A-B).

In some embodiments, active layer 1402 thickness is about 50 μm with a resistance between about 0.5 to about 3 Ohm/cm. in some embodiments, insulation layer 1404 thickness is about 1-10 μm. in some embodiments, handle layer 1406 thickness is between about 200-600 μm and resistance between about 1 and 100 Ohm/cm.

In an exemplary embodiment of the invention, processing steps comprise treatments of the upper cells surface, including, for example, one or more of: light trapping texture, passivation, and Anti-Reflective Coating (ARC). In some embodiments, texturing or “roughening” of the surface reduces reflection and light trapping increases the optical path length, and can be accomplished in a number of ways. For example etching along the appropriate Si crystal planes can result in a surface made up of pyramids.

Good Si surface passivation and ARC can be accomplished, for example, by plasma deposition of thin silicon nitride dielectric layer. In GaAs ultra thin layer of AlGaAs window is optionally used.

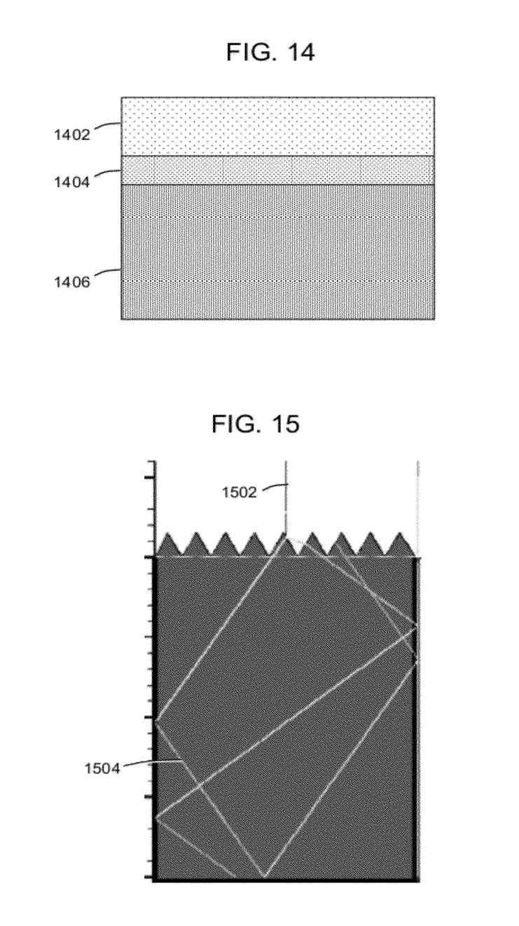

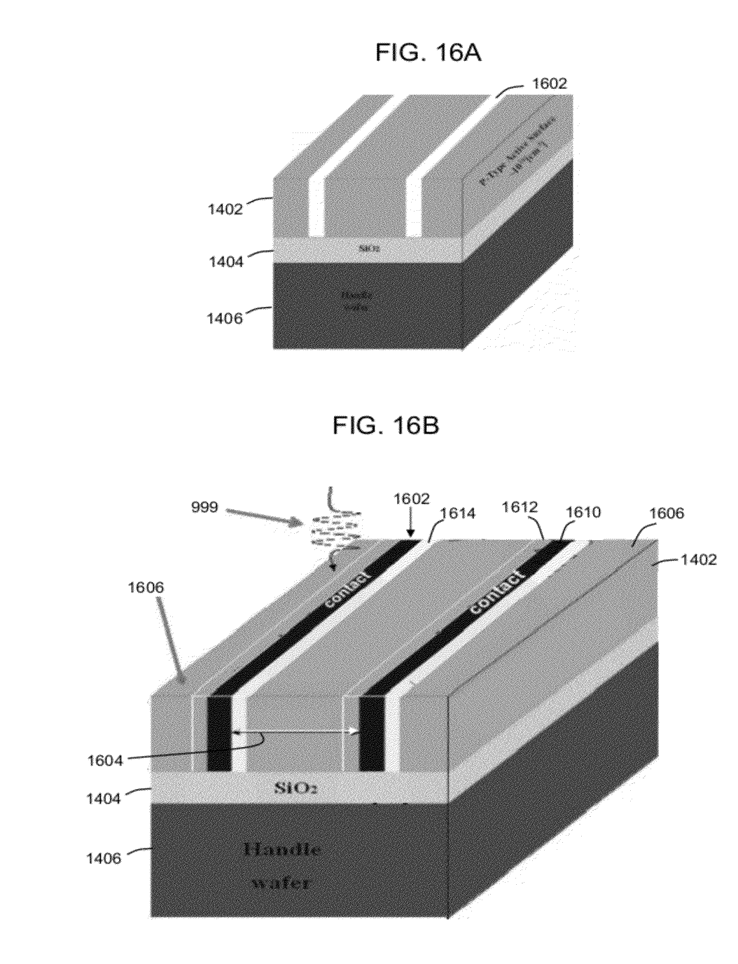

FIG. 15 schematically illustrates a simulation results for the light path in a junction with pyramids textured surface, in accordance with an exemplary embodiment of the invention. The incident light 1502 is refracted and reflected in a plurality of paths inside the junction (trapped). Reflection from the sides is typically from the metal between the junctions and from the bottom is typically due to reflective layer under the junction, (see for example, FIG. 14 and FIG. 16B).

In some embodiments, separate junctions may be formed in the active layer by forming narrow trenches that separate the junctions (narrow trenches e.g. relative to the separation between the trenches). The inactive area due to the trenches is optionally minimized by keeping the trenches as thin as practically possible and/or desired. The depth of the trench should optionally fit the depth of the active layer (e.g. layer 1402 of FIG. 14). Fabrication of trenches with depth to width high aspect ratio can serve for dual purposes: first for the formation of the vertical junction and second for the fabrication of thin vertical trench filled with metal contacts lines (see FIG. 16B), realizing the series connection of adjacent junctions. These trenches can be realized, for example, by technologies of Deep Reactive Ion Etching—DRIE or by anisotropic wet etching.

FIG. 16A schematically illustrates fabrication of vertical high aspect ratio trenches by anisotropic etching technologies, in accordance with an exemplary embodiment of the invention. With reference to FIG. 14, trenches 1602 are fabricated in active layer 1402.

FIG. 16B schematically illustrates a structure of a monolithic silicon VMJ cell formed based on the structure of FIG. 16A, in accordance with an exemplary embodiment of the invention.

A cell extent (width), taking into account the repeating structure, is indicated by a arrow 1604, with adjacent cells 1606 at each side thereof. A junction is formed on a doped bulk 1402 by N-doping through the sidewall of trench 1602 side 1612 and P-doping 1614 through the opposite sidewall of an adjacent trench.

A trench 1602 is filled with electric conductor (e.g. metal alloy) 1610. The general direction of radiation is indicated by jagged line 999 above top layer 1402.

In some embodiments, a cell width and height are between about 40 μm to about 50 μm and the width of doping areas is about 0.5 μm and the width of the conductor is between about 10 μm to about 1 μm. In some embodiments, other dimensions are used.

In some embodiments, the bulk is P-doped and a PN junction is formed by N-doping a trench side, and the P-doping at another side of a trench (in larger concentration of the bulk) is used for electrical interface with conductor 1610 (e.g. reducing resistance between the junction and the conductor). In some embodiments, the bulk is N-doped and a PN junction is formed by P-doping a trench side, and the N-doping at another side of a trench (in larger concentration of the bulk) is used for electrical interface with conductor 1610.

The geometry of the trenches may have an essentially rectangular cross-section with high aspect ratio as shown, for example, in FIG. 16. Alternatively, the trenches may have other high aspect ratio cross sections, such as an essentially triangular cross-section (V-grooves) as illustrated in FIG. 18, or trapeze cross-section or cylindrical cross-section. In some cases formation of vertical junction through high aspect ratio rectangular trench may pose some difficulties which, in some embodiments, may be overcome by fabricating V-shaped or trapezoid trenches. The relative (e.g. with respect to vertical) wide opening of the V-trench may permit easier access for applying doping and the conductive materials for electrical contacts (for example, by implementation by ion gun slanted towards the inner side of a trench, e.g. the side of a trench is slanted about 30 degrees and the gun is slanted about 20-30 degrees respectively).

Contemporary solar cells do not use the vertical junction structure and therefore do not use vertical trenches. In some cases, contemporary vertical junctions cells are produced by mechanical stacking of separate wafers and do not use the trench structure. Therefore the use of narrow trenches in PV cells to create separation between adjacent junctions is deemed to be novel.

In silicon, the depth of the active layer and the depth of the trenches can typically be about 30 to 100 microns. Optionally, if the depth of the active layer and the trenches is less than about 100 microns, then a reflecting layer is added at the bottom of the cell. The width of each junction can be between 50 and 300 microns, and this dimension depends, for example, on the carrier lifetime that characterizes the specific crystal quality of the wafer. The width of the trench between junctions may be less than 5% of the junction width, and optionally less than 3% (or 1%) of the junction width.

The vertical junctions may be formed by sidewall doping. The junctions may be formed by doping into one sidewall of the trench donor atoms (or ions) to form an N+ region, and doping into the opposite sidewall of the trench acceptor atoms to form a P+ region. This can be implemented by directed ion implantation or diffusion technology when one sidewall is covered, with two steps of doping, one for each sidewall. One example of an optimal penetration depth, as predicted by the device simulation, for some embodiments, may be about 0.5 microns.

In some embodiments, trenches are made as thin as practical (see also above) and conductors (e.g. metal) are deposited in the trenches, thus the conductors between the junctions (sandwiched therebetween) have a thin aspect ratio (small proportion) along the surface of the junctions (cell), such as about or less than about 6%, 5%, 3% or 1%. Consequently the active area of the cell comprises a large proportion of the area of the cell, such as about or more than about 94%, 95%, 97%, 98%, or 99%.

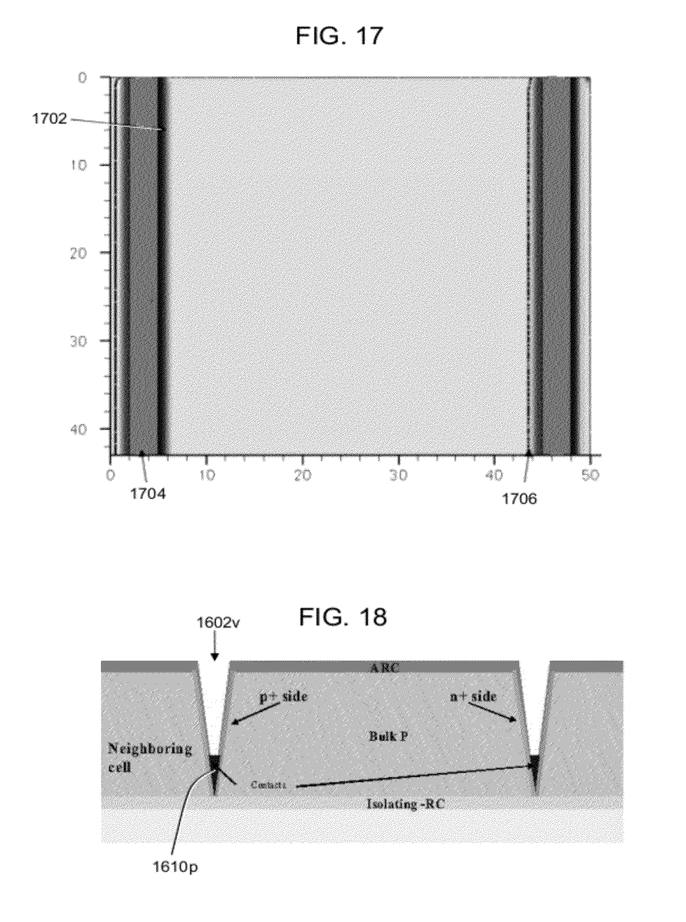

FIG. 17 illustrates an example of process simulation of Ion Implantation through trench sidewall implementing with the Synopsis TCAD Sentaurus process simulator tool, illustrating simulation results of internal structure of neighboring junctions in a vertical multi-junction by directed ion implantation through high aspect ratio trench sidewalls.

The vertical axis is the height or thickness (as for example, in FIG. 14) in μm and the horizontal axis is the width (between trenches) in μm. The region indicated as 1702 is doped with P-type boron (e.g. 10¹⁹ cm⁻³) the region indicated as 1704 is metal and the region indicated as 1706 is doped with N-type phosphorous (e.g. 10¹⁹ cm⁻³). The bulk is P-type boron doped (e.g. 10¹⁶ cm⁻³) with lower concentration of the P-type region 1702.

Exemplary process parameters for achieving doping similar or according to the illustration of FIG. 17 are presented in Table-1 and Table-2 below.

TABLE 1
Implantation parameters
for P+ Junction

| # | Condition | Value |
|---|---|---|
| 1 | Doping | P-Type |
| 2 | Dopant | Boron |
| 3 | Dose | ~10¹⁷ [cm⁻²] |
| 4 | Energy | 150 [KeV] |
| 5 | Wafer Tilt | 3° |

TABLE 2
Implantation parameters
for N+ Junction.

| # | Condition | Value |
|---|---|---|
| 1 | Doping | N-Type |
| 2 | Dopant | Phosphorus |
| 3 | Dose | ~10¹⁷ [cm⁻²] |
| 4 | Energy | 150 [KeV] |
| 5 | Wafer Tilt | −3° |

The process of doping the sidewall of a deep trench (high aspect ratio) is feasible, as shown, for example, in S. Nizou a,b, M. Ziti a, C. Dubois c, M. Roy b, D. Alquier, Ultra deep trench doping in silicon by grazing incident Boron implantation, Nuclear Instruments and Methods in Physics Research B 257 (2007) 275-278, which discloses to introducing an identical dopant material into both sides of the trench. In an exemplary embodiment of the invention, a new approach of two different dopants to the two sidewalls of the trench is applied, thus creating a junction in-situ. This can be realized, for example, by either of two fabrication methods. One is to use ion implantation at grazing angle, in two subsequent implantation steps with different dopant materials and opposite angles for each wall of the trench. A second method is to cover alternate sidewalls of the trench by a photoresist (or other removable layer or masking the beam), and then using diffusion technology to introduce the dopant into the exposed sidewall.

The electrical contact between each pair of adjacent junctions is optionally formed by filling the trenches with one or more conductive materials, which will create a low resistance ohmic contact simultaneously with the N+ and the P+ regions in the two sidewalls of the trench. Trenches may be filled for example using Vapor Phase Epitaxy (VPE) technologies or Electroplating deposition methods.

Conductive materials for the contact are optionally chosen from the group of: metals, such as aluminum, copper, titanium, nickel, gold, or combinations and alloys thereof, and semiconductors such as highly doped polysilicon.

If the trench is filled with a single conductive material, then improved compatibility with the both sidewalls and one step of annealing are optionally achieved by using a suitable alloy such as the ternary Ni/Ti/Al materials with various compositions as described, for example, in S. Tsukimoto, T. Sakai, T. Onishi, Kazuhiro Ito, and Masanori Murakami, Simultaneous Formation of p- and n-Type ohmic contacts to 4H-SiC using the ternary Ni/Ti/Al system, Journal of Electronic Materials, Vol. 34, No. 10, 2005.

If the contacts are formed with two or more conductive materials, then the materials are optionally deposited in several steps one after the other. Optionally, a deposited layer of metal can serve as shield or cover of one sidewall during the doping processes.

In typical prior art vertical multi-junction cells, the ohmic contact between adjacent junctions is apparently created by a metallic layer deposited on the side surfaces of the separate wafers before they are connected mechanically. The deposition of a metallic contact in-situ inside the trench attaching the N+ and the P+ is a new approach which may be made part of the monolithic fabrication process.

In some embodiments, the trenches may be filled only partially with the conductive materials, to create localized contacts, so the rest of the trench is empty. The part of the sidewalls facing the empty part of the trench is optionally passivated. The part of the trench sidewall that is not coated with the conductive materials can absorb additional incident radiation and reduces the loss due to cell inactive area.

Decreasing the metal contacts area reduces recombination at the semiconductor-to-contact interface. On the other hand, this may impose higher series resistance and limit the cell efficiency with increasing concentration. The fraction of the trench that is filled is optionally optimized for a given concentration ratio.

FIG. 18 schematically illustrates V-trenches 1602v with partially filled localized contacts 1610p, in accordance with an exemplary embodiment of the invention.

### Lift-Off Process

An alternative approach to starting with an active layer on top of an insulator is a lift-off process that starts with a substrate without the insulating layer. A thin sacrificial layer is deposited on the substrate, and then the bulk material of the active layer is grown on the sacrificial layer. Processes such as described above may be performed to create the junctions structure, doping, and contacts. The sacrificial layer may be selectively etched and the interface that was between it and the bulk would be the front surface of the cell (towards the radiation).

The trench geometry is optionally selected as V-groove or trapeze such that the wide end is open and accessible fabrication processes, and the narrow end of the trench is adjacent to the front surface of the cell, optionally reducing the inactive area of the cell.

Optionally, an isolating carrier handle wafer is attached to the upper side (eventually back side opposite the radiation), and the sacrificial layer is etched and released from the bottom side of processed active layer, exposing the front surface of the cell. The front surface of the cell may then be treated as described in above (e.g. light trapping texture, passivation, and anti-reflective coating).

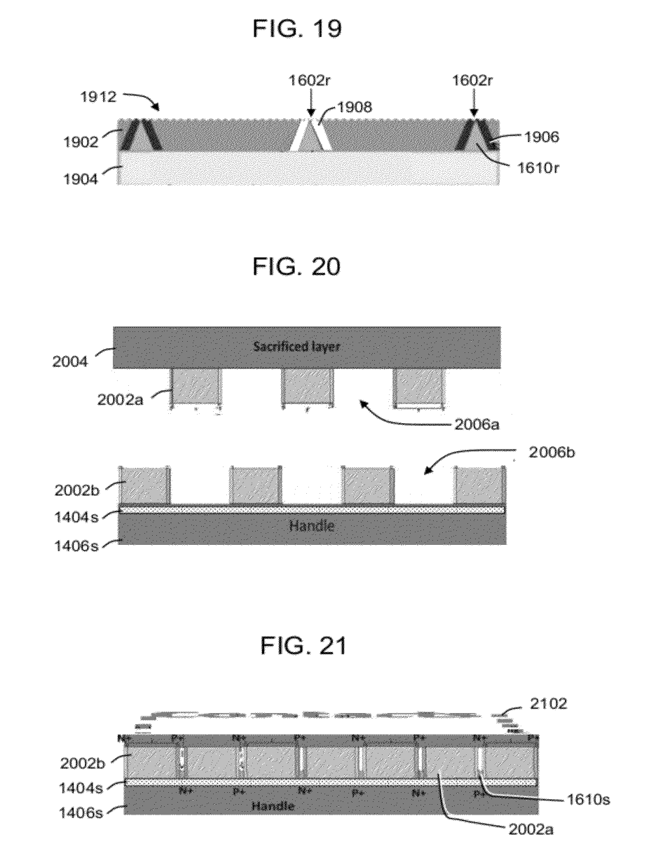

FIG. 19 schematically illustrates VMJ after a lift-off process, in accordance with an exemplary embodiment of the invention.

V-trenches 1602r are formed akin to V-trenches 1602v of FIG. 18 but in opposite direction (relative to the radiation). The sides of each alternating trench 1602r are doped with N+ doping 1606 and P+ doping 1908 forming junctions with the bulk 1902 (either N-doped or P-doped). Akin to contacts 1610 and 1610p or FIGS. 16B and 18, respectively, an electric conductor 1610r, such as a metal alloy, is deposited in trenches 1602r.

Bulk layer (“active”) 1902 is attached to isolation carrier wafer 1904, akin to layers 1402 and 1404 of FIGS. 14 and 16A-B).

The top surface of the cell (lower surface in the process) is shown with texturing 1912.

With ‘inverted’ trenches 1602r the fraction of the area of the front side of the cell that is devoted to the trenches and electrical contacts may be reduced or minimized and the incident radiation is optionally then absorbed into the active area of the cell with reduced or minimal losses relative to cell of FIG. 18 fully filled with conductive material.

The Lift-off process can, in some embodiments, be summarized as follows:

(a) A wafer as a bulk is processed to form VJ. The bulk is analogous to the active layer in SOI above, but an “active” layer does not exist because in liftoff SOI is not used

(b) Attaching external isolating carrier to the bulk. The carrier is analogous to the SiO2 in SOI but is some embodiments instead of SiO2 other insulating material (such as materials useful for mechanical handling).

(c) Disconnecting the processed bulk by selective etch from the original wafer and making the etched interface the upper light absorbing interface.

(d) surface treatments.

It should be noted that unlike the cells of FIGS. 16B, 17 and 18, the sides of the trenches of the cell of FIG. 19 may formed with similar or identical doping, with the doping alternating with alternating adjacent trenches (or junctions).

### Semi-Monolithic Process

An alternative process to fabricate VMJ cells uses monolithic processing with a single additional mechanical stacking step.

In some embodiments, the process can begin by using two substrates (wafers): one insulating as, for example, 1404 of FIG. 4, e.g. SiO₂, and the other may be any substrate with sacrificial thin layer. Both substrates should have an active layer or bulk with matching parameters (e.g. background doping).

In some embodiments, a similar process is performed on the two substrates. In some embodiments, wide vertical trenches with matched thickness and separation distances are fabricated so that the width of a trench in one wafer can fit the width of the junction in the other wafer possibly with additional the width needed to form two contacts between each junction. In some embodiments, the trenches are ‘wide ’ relative to trenches between densely packed adjacent junctions such as illustrated in FIG. 16B.

Optionally, the junctions are formed by opposing doping through the sidewalls of the “wide” trenches as described above (e.g. with respect to FIG. 16B or 17). The doping processes can be easier and less expensive relative to the monolithic approach described above due to the large width of the trenches, allowing easy access to the sidewalls.

FIG. 20 schematically illustrates two processed wafers prepared for mechanical matching stacking, in accordance with an exemplary embodiment of the invention.

On a sacrificial layer 2004 are formed junctions 2002a, and on a substrate 1404s 1406s (akin to 1404 insulating and handle layer 1406 of FIG. 14) are formed junctions 2002b. Junction 2002a and 2002b are separated by trenches 1406a and 1406b, respectively, such that junctions 2002a can fit in trenches 2006b and junctions 2002b can fit in trenches 2006a, while, optionally, leaving margins between the junctions such as to apply electrical conductors between the junctions.

In some embodiments, the two wafers are mechanically stacked, leaving narrow gaps between the junctions for electrical contacts, to form the complete VMJ cell.

Following the formation of the complete VMJ cell structure, the sacrificial layer and its substrate can be removed.

In some embodiments, the electrical contacts are fabricated by depositing one or more conductive materials in the narrow trenches (gaps) that remain after the mechanical stacking step, as described, for example, for the monolithic approach or, in some embodiments, a conductive adhesive is used in the gaps and/or then stacking the wafers).

The front surface of the cell may be treated after formation of the electrical contacts, including for example: light trapping texture, passivation, and Anti-Reflective Coating (ARC), as described above.

FIG. 21 schematically illustrates a VMJ cell constructed from the wafers of FIG. 20, in accordance with an exemplary embodiment of the invention. Junctions 2002a and 2002b are interleaved therebetween, sacrificial layer 2004 is removed, electrical conductors 1610s (akin to 1610 of FIG. 16B or 1610p of FIG. 18) deposited in the margins between junctions 2002.

In some embodiments, more than two wafers are used as described above enabling to connect the junctions into a larger (longer) cell.

Monolithic Process with Pore Contacts

The monolithic process with pore contacts, described below, is, in some embodiments, applicable to single crystal material such as Si and III-V materials.

In some embodiments, the basic structure comprises a substrate, a thin sacrificial (release) layer on top of the substrate, and an active bulk layer on top of the release layer, similar to the Lift-off process described above.

Deep cavities, or pores, with high aspect ratio are etched in the active layer, for example, through a mask using known technologies such as anisotropic wet etch. The cross section of the pore may be essentially circular, or rectangular, or any suitable shape.

In some embodiments, the shape of the cavity is elongated into the material with tapering sidewalls, ending with a tip or with a small planar surface at the release layer. For example, if the base of the pore is a square, then the pore will be shaped as a pyramid with its tip at the release layer, or a pyramid frustum with its top surface at the release layer.

In silicon, the depth of the active layer and the depth of the pores can typically be, in some embodiments, about 30 to 100 microns, for example, about 50 microns. Optionally, if the depth of the active layer and the trenches is less than about 100 microns, then a reflecting layer is added at the bottom of the cell.

In some embodiments, the pores do not extend throughout the active layer, whereas in some embodiments, the pores extend through and/or beyond the active layer.

In GaAs, the depth of the active layer and the depth of the pores can typically be, in some embodiments, between about 1 to 5 microns, for example, around 3 microns. The depth of the active layer for other direct-gap III-V materials should be similar to the depth for GaAs.

The separation distances between the pores are determined according to the diffusion lengths of the carriers, corresponding to the cell material and its crystal quality. For example, for silicon the distance between pores may be between 40 microns and 300 microns, and optionally the distance is between 50 and 100 microns.

In GaAs, the distance between pores may be between about 3 microns and 9 microns, and optionally the distance is between about 4 and 7 microns.

In some embodiments, junctions are formed by doping through sidewalls of pores.

Part of the pores may be doped with acceptor atoms to create a P+ region into the sidewalls of each pore. Another part of the pores may be doped with donor atoms to create an N+ region into the sidewalls of each pore. The doping may be performed using diffusion technology or implantation. The process is optionally done in two steps, and in each step a part of the pores is covered and the other part is doped. In this process flow, doping opposing trench sidewalls with different dopants can be avoided as described above. Optionally, the junctions are arranged such that each pore with a specific doping is surrounded by pores with the opposite doping.

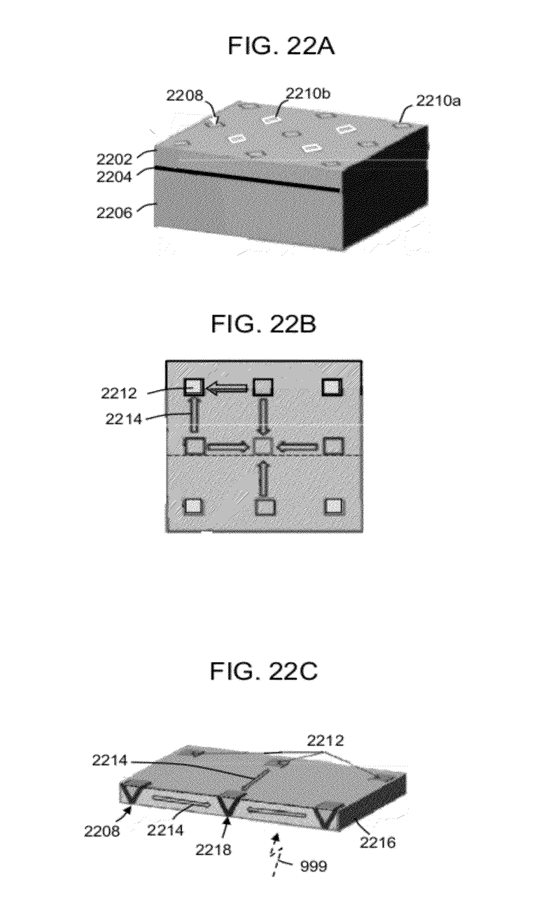

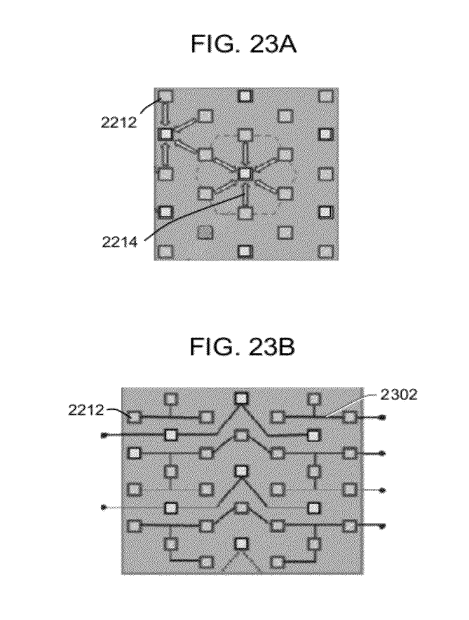

In some embodiments, in order to isolate the individual junctions from each other, a narrow trench is optionally formed to separate electrically groups of pores according to a predetermined pattern (see, for example, FIG. 22A-C for a square pattern and FIG. 23A-B for hexagonal pattern). Exemplary role and arrangement of the isolation trenches is described further below.

Electrical contacts are optionally formed by filling the pores with one or more conductive materials, which will create a low resistance ohmic contact with the N+ and the P+ regions in the sidewalls of the pores. The pores may be filled for example using Vapor Phase Epitaxy (VPE) technologies or Electroplating deposition methods. The conductive material may be different for each set of P+ and N+ pores.

Conductive materials for the contact can be, for example, chosen from the group of: metals, such as aluminum, copper, titanium, nickel, gold, or combinations and alloys thereof, and semiconductors such as highly doped polysilicon. Dielectric deposition layer is usually used to electrically separate the filled pores.

The upper side of the cell (eventually lower side away from the intended radiation) is optionally attached to an electrically isolating carrier back plane, such as a dielectric layer, with contact points and conductive lines. The pattern of contact points on the back plane is matched to the pattern of the pores, isolating the conductive grid from the active layer. Optionally, and isolating handle wafer is attached over the back plane such as to provide mechanical support.

The conductive lines pattern defines a single junction as a set of adjacent pores comprising both P+ and N+ pores, where all P+ pores are electrically connected in parallel by the conductive lines, and all the N+ pores are electrically connected by a second set of conductive lines.

FIG. 22A schematically illustrates a structure for a VMJ cell with pores arranged in rectangular pattern, in accordance with an exemplary embodiment of the invention. On a substrate 2206 is disposed a sacrificial layer 2004 with an active layer 2202 on top thereof. Into active layer 2202 are formed pores 2208 with doping 2210a and 2210b (e.g. P-doping and N-doping indicated with different shades) on the sides thereof thereby forming junctions.

FIG. 22B-C schematically illustrates a structure for a VMJ cell with pores 2208 arranged in rectangular pattern with attached contacts 2212 and current directions 2214 interconnections therebetween in top and perspective cross-section, respectively, in accordance with an exemplary embodiment of the invention. The different shadings indicate different doping (e.g. P-doping or N-doping).

In FIG. 22C a section of the VMJ cell is illustrated after removal of sacrificial layer 2204 with the top side 2216 towards intended radiation (indicated as dashed arrow 999).

In some embodiments, ending a pore with a tip 2218 or with a small planar surface allow to reduce or minimize the inactive portion of the cell while providing access for doping and/or metallization of the pores from the opposite wider end thereof.

FIG. 23A-B schematically illustrates a top view of a structure for a VMJ cell with pores arranged in hexagonal pattern with attached contacts 2212 and current directions 2214 and electrical connections 2302 therebetween, respectively, in accordance with an exemplary embodiment of the invention. The different shadings indicate different doping (e.g. P-doping or N-doping).

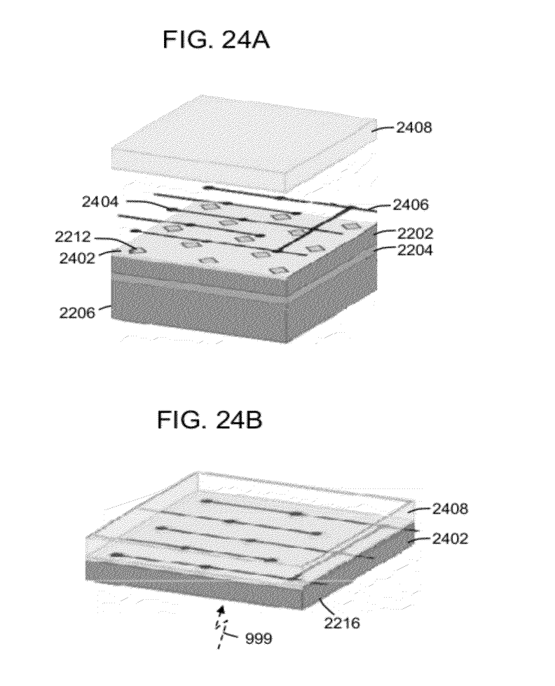

FIG. 24A-B schematically illustrates perceptive views formation of contacts and exposure of upper surface, respectively, of VMJ cell with pores arranged in a rectangular pattern, in accordance with an exemplary embodiment of the invention.

With reference also to FIG. 22A-C, FIG. 24A illustrates substrate 2206 under a sacrificial layer 2204 under an active layer 2202. On top of active layer 2202 is deposited a dielectric layer 2402 with holes (openings) that expose the contacts 2212 over the junctions formed in the pores. Over dielectric layer 2402 are deposited junction grid contacts 2404 and contacts grid 2406 for interconnecting the junctions. An isolating handle wafer 2408 is optionally attached over dielectric layer 2402. It should be noted that the order of the components (top-bottom) is reversed in the sense that the topmost component is a bottommost with respect to the intended radiation direction.

FIG. 24B illustrates the structure of FIG. 24A after removal of the sacrificial layer (lift-off). The lower side of active layer 2202 is eventually the top side 2216 towards intended radiation (indicated as dashed arrow 999).

The defined junctions may be connected electrically in series by connecting one conductor from a first junction, for example the P+ conductor, to the opposite type conductor line, for example N+, of a second junction. Each group of pores defined as a junction is isolated from the neighboring group by the separation trenches, and the electrical contacts between junctions are optionally formed only via the back plane conductive lines grid.

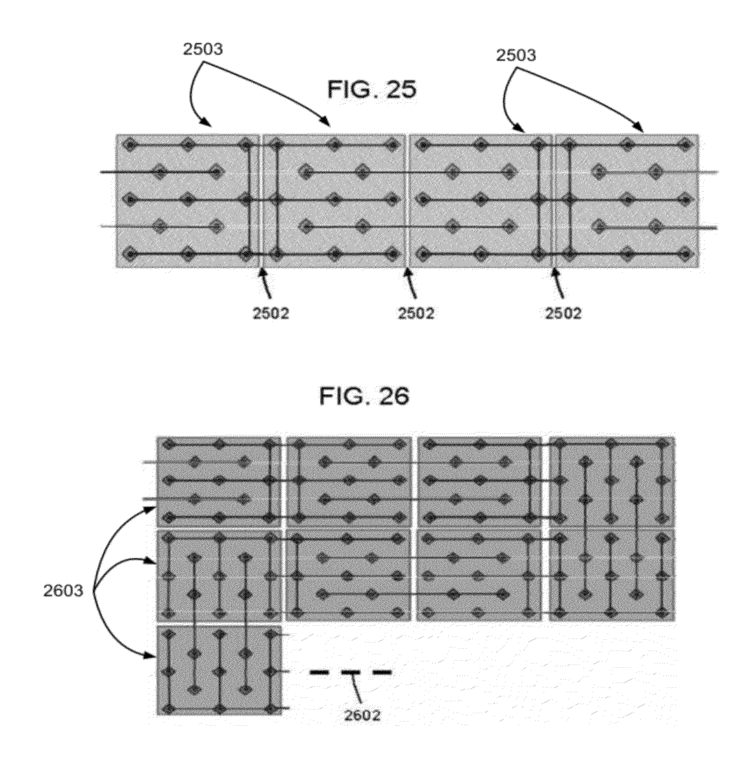

FIG. 25 schematically illustrates a top view series connection of junctions of VMJ cell based on pores with isolation trenches 2502, defining electrically isolated areas 2503, in accordance with an exemplary embodiment of the invention. In some embodiments, the cell is monolithic, or, optionally, a part of a monolithic structure.

A set of adjacent junctions connected in series may be defined as a subcell. A plurality of subcells may be formed within a single cell by forming an appropriate arrangement of the conductive lines in the back plane. The arrangement and connection order of junctions to form a subcell may be in different layouts. Subcells may be connected electrically in parallel or in series.

In some cases, all junctions within a cell may be connected in series and there are optionally no separate subcells. For example, in Si cells, if each junction width is about 100 microns, then a 1 cm wide cell would produce an acceptable voltage of about 60 Volts when all junctions are connected in series. In other cases, for example, in cells made from III-V materials, if all junctions are connected in series then the resulting voltage may be too high. Therefore, it may be desirable to produce a moderate cell voltage by dividing the cell into subcells and connecting a set of subcells in parallel to achieve the desired cell voltage.

FIG. 26 schematically illustrates a top view of electrical connections of a set of junctions that form a subcell, in accordance with an exemplary embodiment of the invention. Dashed line 2602 indicates that the connections may be extended.

FIG. 26 also depicts electrically isolated areas 2603, similarly to FIG. 25.

After attachment of the back plane, the release layer is optionally etched and removed with the substrate. The front surface of the cell may be treated after removal of the release layer, including for example: light trapping texture, passivation, and Anti-Reflective Coating (ARC), for example, as described above.

### Tandem VMJ Cells

The monolithic and semi-monolithic (mechanical stacking) approaches may also be used as steps toward an implementation of VMJ tandem cells (multi-tier, stack). This approach combines the advantages of the VMJ architecture with the high efficiency potential of using multiple spectral bands.

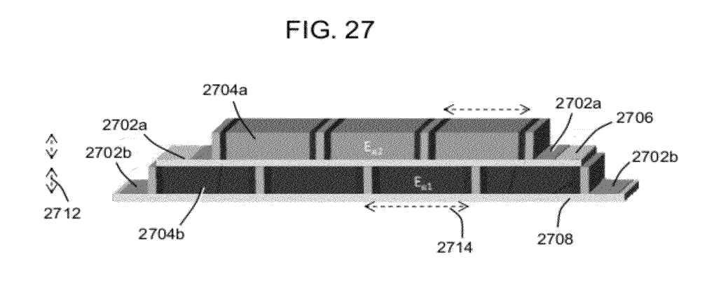

FIG. 27 schematically illustrates a four-terminal (two-tier, two-layer) VMJ tandem cell with different number of junctions in each active layer and separate electrical connections for each active layer, representing any number of tiers an junctions, in accordance with an exemplary embodiment of the invention.

In some embodiments, each of the layers contains a VMJ cell made form a different material and comprising junctions 2704a and 2704b internally connected in series. A thin layer 2706 (e.g. thin relative to a junction thickness 2712) made of a transparent and electrically isolating material separates the two layers of the VMJ cells. The width 2714 and number of junctions in each layer may be different. A similar structure may be implemented with any number of layers, for example three active layers separated by two isolating and transparent layers 2706.

When the voltage produced by the layers is different, each layer may have a separate set of electrical terminals 2702. The cell may be, for example, a four-terminal 2702a and 2702b cell (two layers) or a six-terminal cell (three layers). In some embodiments, each layer operates as a separate cell and there no need to match voltage or current among the different layers. Optionally, the number of junctions in each layer may be adjusted such that the overall voltage produced by all layers is the same or sufficiently close, so that a single set of electrical terminals may be connected to all layers in parallel.

For example, a two-layer tandem VMJ cell may be produced as follows. A VMJ cell from material with bandgap Eg1 is fabricated on an insulating substrate using methods such as described above. Another VMJ cell made from a material with bandgap Eg2 is made on a substrate with a release layer according to the Lift-off methods such as described above. The two cells are mechanically stacked together with an additional thin insulating and transparent layer. The release layer on the second cell is optionally etched and removed together with its substrate. Finally, surface treatments to reduce reflectivity are optionally applied to the top surface of the tandem cell as described above.

### Brief Outline of Fabrications

Below are briefly outlined some of the fabrication methods for vertical junction PV cells (VMJ).

### Monolithic

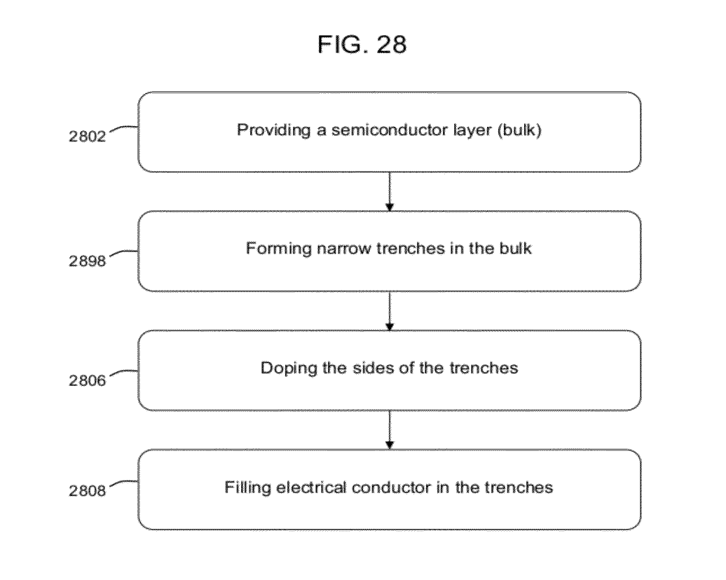

FIG. 28 outlines a method for monolithic fabrication of vertical junctions PV cells, in accordance with an exemplary embodiment of the invention.

A semiconductor bulk (wafer) is provided, e.g. Si or GaAs (2802). In some embodiments, the bulk is pre-doped and optionally provided with underlying insulation layer such as a Silicon-On-Insulator (SOI), where in some embodiments, the bulk is separately doped.

Spaced apart narrow trenches are formed in and through the bulk (2804), wherein in some embodiments, narrow is relative to the space between the trenches.

Regions at the sides of the trenches are doped to form junctions (2806). In some embodiments, a junction is formed by a dopant different than the doping of the bulk, and in some embodiments, a side of a trench is doped with the same or similar dopant as the bulk but with high concentration to provide electrical conductance at a junction side.

The trenches are filled, at least partially, with electrical conductor such as a metal alloy (2808) to provide electrical connection between the formed junctions. As such, the conductors are sandwiched between the formed junctions.

### Semi-Monolithic

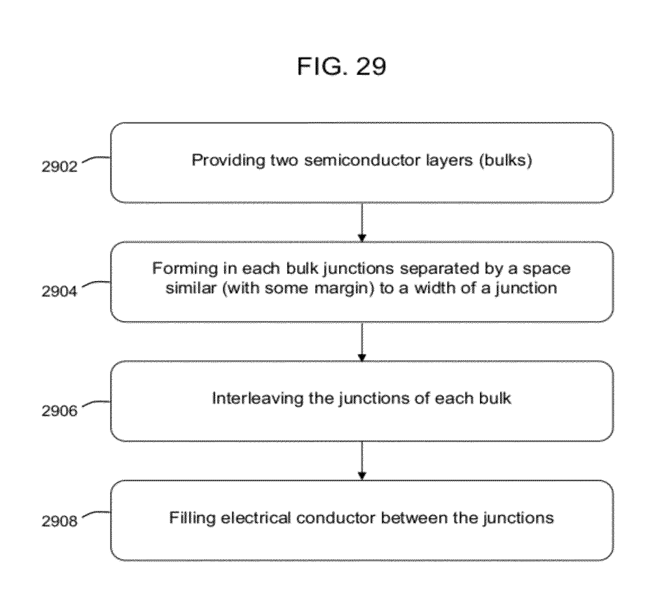

FIG. 29 outlines a method for semi-monolithic fabrication of interleaved vertical junctions PV cells, in accordance with an exemplary embodiment of the invention.

Two (or more) semiconductors layers (bulks) are provided (2902). In some embodiments, one bulk is on a support such as a handle and the other bulk is on a sacrificial layer.

In each bulk are formed junctions (e.g. by doping a side and/or two sides thereof) wherein the junctions are separated by a space similar (with some margin) to a width of a junction (2904). The spaces between the junctions in one bulk are formed to fit the width of the junction of the other bulk providing margins for filling a conductor see below.

The junctions of each bulk are interleaved so that junctions of one bulk fit between the spaces of the other bulk (2906). In some embodiments, the interleaved junctions are bonded together with each other or otherwise attached.

The remaining spaces between the junctions are filled, at least partially, with an electrical conductor (2908) to provide electrical conduction between the junctions.

### Pores

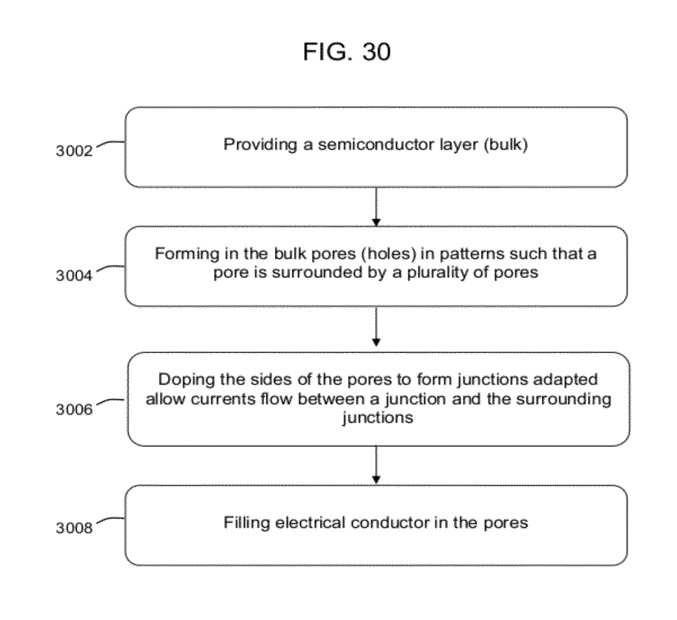

FIG. 30 outlines a method for fabrication of vertical junctions formed in pores, in accordance with an exemplary embodiment of the invention.

A semiconductor bulk (wafer) is provided, e.g. Si or GaAs (3002). In some embodiments, the bulk is provided on a sacrificial layer which is subsequently removed.

In some embodiments, the bulk is pre-doped where in some embodiments, the bulk is separately doped.

Pores (holes) are formed generally vertical to the bulk surface in patterns such that a pore is surrounded by immediate plurality of neighboring pores (3004).

The sides of the pores are doped to form junctions adapted allow currents flow between a junction and the surrounding junctions (3006). For example, one junction is immediately (with no intervening pores or junctions) surrounded by six junctions such that current can flow between the junction and the six surrounding junctions.

The pores are filled, at least partially, with an electrical conductor (3008) to provide electrical conduction between junctions.

### Vertical Multi Junction (VMJ) Cell Structure—Two-Dimensional (2D) VMJ Cells

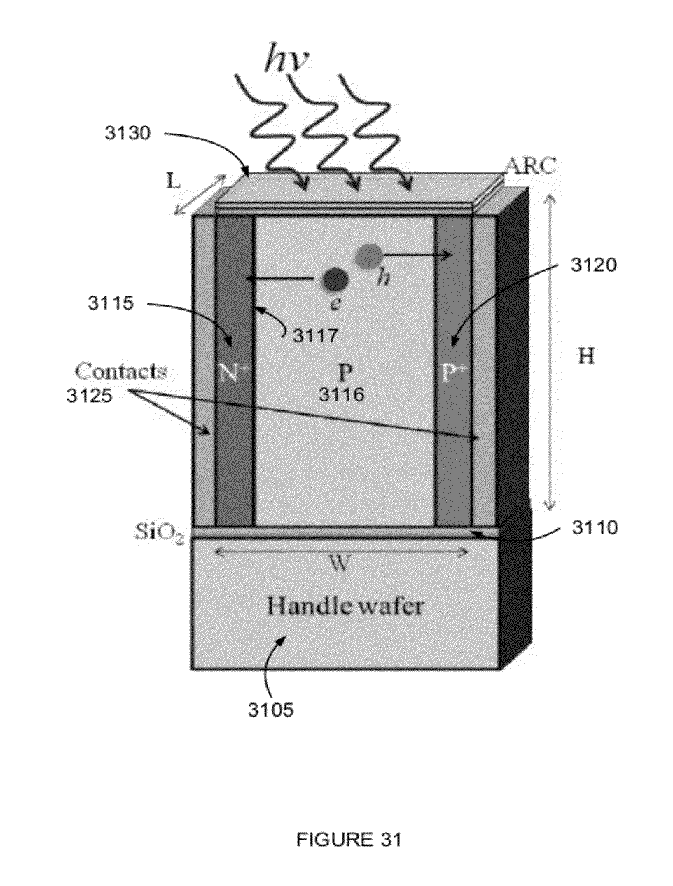

Reference is now made to FIG. 31, which is a simplified schematic illustration of a vertical junction photovoltaic cell, of which several are included in an example embodiment of the invention.

FIG. 31 depicts a structure of an example single 2D VMJ cell. A VMJ high-voltage panel optionally includes many of the VMJ structures side-by-side, electrically series-connected, optionally via vertical metallic contacts.

The example VMJ cell of FIG. 31 includes:

a substrate, or handle, wafer 3105, of which only a small portion is depicted in FIG. 31;

a layer of insulation 3110, by way of example a SiO₂ layer;

an N⁺ 3115 portion of semiconductor material, and a P³⁰ 3120 portion of semiconductor material, between which is a portion of semiconductor material 3116, optionally P-doped;

a junction 3117 layer at an interface where the P and N+ layers meet. The thickness of the junction 3117 is not depicted to scale in FIG. 2. The P 3120 portion optionally forms a bulk of the VMJ cell. The P+ 3120 portion on a side opposite the junction 3117 is an intermediate layer which provides a good electrical connection to a metal contact 3125;

contacts 3125 adjacent to the N⁺ 3115 portion and the P⁺ 3120 portion, optionally metallic; and optionally,

a passivation layer 3130.

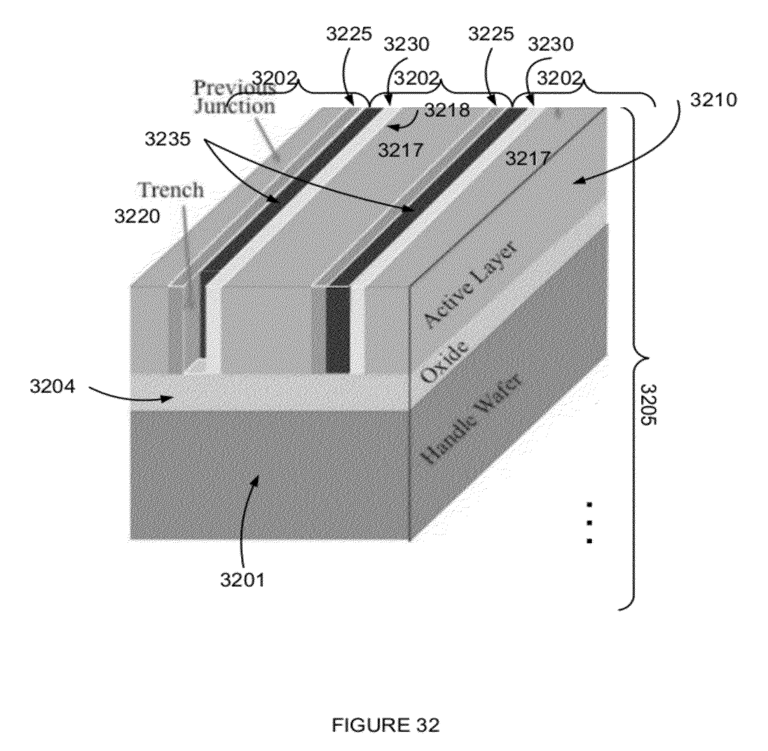

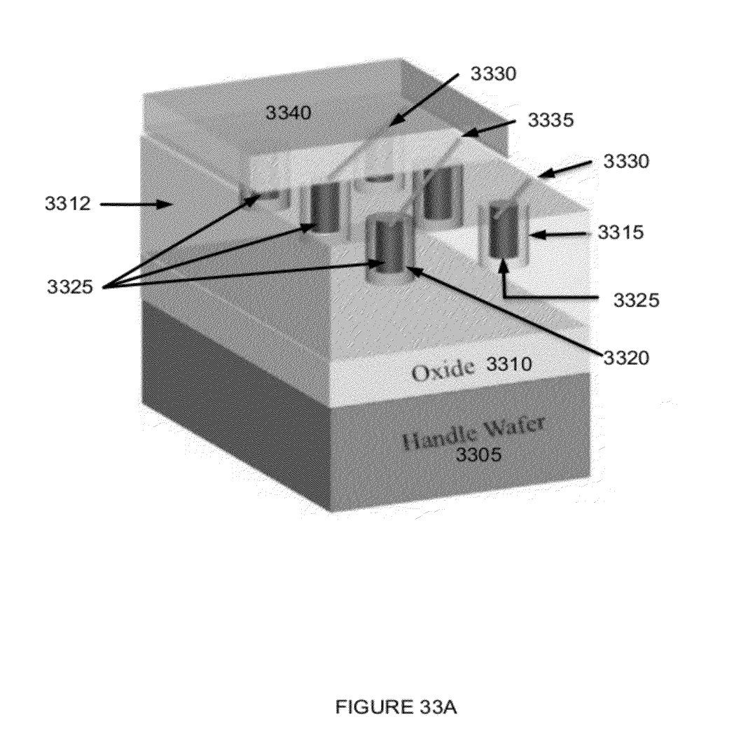

Reference is now made to FIG. 32, which is a simplified schematic illustration of two-dimensional VMJ photovoltaic cells 3202, fabricated in an active layer of a Silicon-On-Insulator (SOI) device, in accordance with an example embodiment of the invention.

FIG. 32 provides an illustration, with reference to which a description how VMJ cells 3202 may be fabricated in an active layer 3210 of a Silicon-On-Insulator (SOI) device. A non-limiting example of a monolithic cell fabrication process is now described, based on the schematic structure depicted in FIG. 2.

The example VMJ cell of FIG. 32 includes:

a substrate, or handle, wafer 3201, of which only a small portion is depicted in FIG. 32;

a layer of insulation 3204, by way of example a SiO₂ layer; and

an active layer 3210.

The active layer 3210 includes, after fabrication of the cell:

an N⁺ 3230 portion of semiconductor material, and a P³⁰ 3225 portion of semiconductor material, between which is a portion of semiconductor material 3217 of semiconductor material, optionally P-doped. At an interface where the N+ 3230 portion and the portion of semiconductor material 3217 meet, a junction 3218 is formed;

contacts 3235 adjacent to the N³⁰ 3230 portion and the P⁺ 3225 portion, optionally metallic; and optionally,

a passivation layer (not shown).

Optionally, the fabrication process may be started using as a starting material a FZ (Floating Zone) SOI (Silicon on Insulator) wafer 3205. The VMJ cells 3202 are fabricated in the active layer 3210, which may optionally be P or N type doped.

Optionally, front surface treatments (not shown) such as, by way of a non-limiting example, texturing, passivation, and antireflective coating are applied to the SOI wafer 3205.

Trenches 3220 are then etched in the active layer 3210 of the SOI wafer 3205, optionally by RIE (Reactive Ion Etching).

In some embodiments of the invention, the trenches 3220 are optionally narrow in relation to their depth. The width of the trenches 3220 should be such as to leave room for fabrication of contacts within the trenches 3220, optionally wide enough so as to provide good conductance.

In some embodiments of the invention, the trenches 3220 are deep enough to reach the bottom of the active layer 3210.

In some embodiments of the invention the thickness of the active layer 3210 is determined in order to: optimize the radiation absorption; charge collection, surface recombination, and so on. In some embodiments of the invention such optimization is performed using computer simulation. By way of a non-limiting example, in silicon, an optimum thickness for the active layer 3210 is approximately between 50 and 100 microns.

N⁺ 3225 portions and P⁺ 3230 portions of the VMJ cells 3202 are optionally produced by directed ion implantation of N⁺ and P³⁰ through the side walls of the trenches 3220.

Finally the trenches 3220 are coated or filled by a conductor, to produce contacts 3235, optionally metal, forming series connection contacts between the VMJ cells 3202.

It is noted that FIG. 28 and its description above describe a similar process.

### Vertical Multi Junction (VMJ) Cell Structure—Three-Dimensional (3D) VMJ Cells

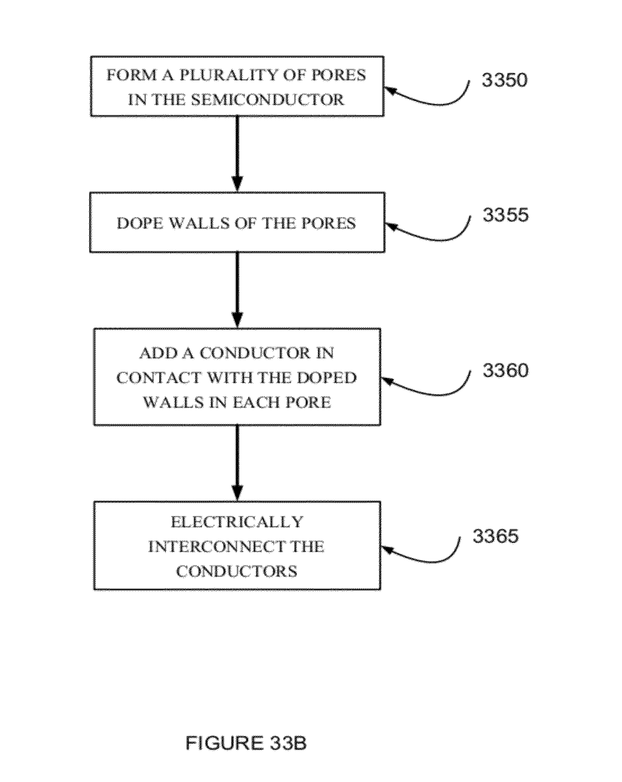

In some embodiments of the invention, a 3D version of the VMJ cell is based on an array of pores, or holes in the active layer, as described below with reference to FIG. 33A.

Reference is now made to FIG. 33A, which is a simplified schematic illustration of three-dimensional VMJ photovoltaic cells, fabricated in an active layer of a SOI wafer in accordance with an example embodiment of the invention.

FIG. 33A provides an illustration, with reference to which a description how VMJ cells may be fabricated in an active layer 3310 of a Silicon-On-Insulator (SOI) device 3305. A non-limiting example of a monolithic cell fabrication process is now described, based on the schematic structure depicted in FIG. 33A.

The example VMJ cell of FIG. 33A includes:

a substrate, or handle, wafer 3305, of which only a small portion is depicted in FIG. 33;

a layer of insulation 3310, by way of example a SiO₂ layer; and

an active layer 3312.

The active layer 3312 includes, after fabrication of the cells:

pores with N⁺ doping in their walls 3320, and pores with P³⁰ doping in their walls 3315, between which is a volume of the active layer 3312, optionally P-doped. Junctions (not shown in FIG. 33A) are formed at interfaces between the pores 3315 3320 and the volume of the active layer 3312;

contacts 3325 within both the N+ pores and the P+ pores, optionally metallic;

a conduction grid 3330 3335 for connecting N+ pores (3335) and P+ pores (3330); and optionally,

a carrier plate (3340).

In some embodiments of the invention the pore depth extends the full thickness of the active layer 3312.

In some embodiments of the invention the pore depth does not extend the full thickness of the active layer 3312. In some embodiments of the invention the pore depth extends to a depth of 50%, 70%, 90%, 95%, or similar percentage of the thickness of the active layer 3312.

It is noted that the structure depicted in FIG. 33A corresponds substantially to the electrically isolated areas 2503 2603 depicted in FIGS. 25 and 26. The electrically isolated areas, or sub-areas, of FIGS. 25 and 26 are separated by isolation trenches 2502. The isolation trenches 2502 of FIGS. 25 and 26, shown as white space in FIGS. 25 and 26, extend a full depth of the active layer and reach the isolation layer. The isolation trenches are not shown in FIG. 33A.

Optionally, the fabrication process may be similar to the 2D case described above with reference to FIG. 32, with changes corresponding to producing pores rather than trenches. Some of the changes include:

doping the walls of the pores in an alternating pattern forms the Vertical Junctions;

filling the pores with a conductor, for example metal;

adding a back conductor grid, producing cell contacts;

attaching the cell contacts of the active layer 3312, optionally using a liftoff process to attach the cell contacts surface to a carrier plate 3340;

optionally etching away the insulation 3310 away, detaching the handle wafer 3305, and exposing cell surface, now termed the front surface; and, optionally,

surface treatments may be applied to the front surface.

In some embodiments of the invention doping the walls of the pores is performed by diffusion. The surface of the active layer 3312 is masked such that only N+ pore locations are open; diffusion of N+ is performed; then the surface of the active layer 3312 is masked such that N+ holes are closed and P+ holes are open, and diffusion of P+ is done performed.

In some embodiments of the invention doping the walls of the pores is performed by ion implantation. The process is similar to that described above with reference to doping by diffusion.

It is noted that doping by diffusion is likely to be less costly than doping by ion implantation.

In some embodiments of the invention, the 3D approach optionally involves a smaller loss of active layer material compared to a trench approach, potentially providing an advantage of a higher efficiency of the cell.

Reference is now made to FIG. 33B, which is a simplified flow chart illustrating a method of manufacturing the example embodiment of FIG. 33A.

The method of manufacturing of a monolithic semiconductor-on-insulator solar cell includes:

forming a plurality of pores in the semiconductor (3350);

doping walls of the pores (3355), forming vertical junctions between the walls of the pores and a bulk of the semiconductor;

adding a conductor in contact with the doped walls in each pore (3360); and

electrically interconnecting the conductors to provide an output voltage of the solar cell (3365).

### Cell Performance Simulation

Sentaurus TCAD device software tools (by Synopsys Inc.) were used to simulate and optimize performance of both the 2D and 3D VMJ cell designs. The simulation setup included realistic properties for the bulk material and the cell surfaces (e.g., recombination velocities).

Simulation of 2D VMJ Cells:

Details of comprehensive 2D optimization studies and results have been recently reported [17]. The studies predict conversion efficiency of close to 30% at a concentration of 1000 suns, and peak efficiency at over 2000 suns, as compared to 26.5% optimal efficiency at 200 suns for conventional Si concentrator cells [19]. Reaching the above-mentioned efficiency is achieved using a junction width of about 50 μm, which is significantly smaller than previous VMJ cells.

Simulation of 3D VMJ Cells:

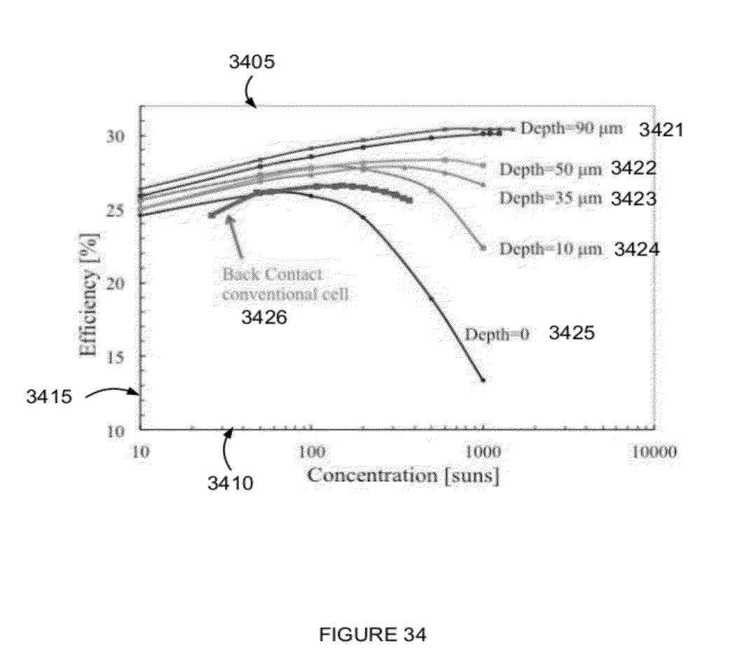

Reference is now made to FIG. 34, which is a simplified graph 3405 illustrating efficiency of three-dimensional VMJ cells produced in accordance with an example embodiment of the invention, vs. radiation concentration 3410 and pore depth.

The graph 3405 of FIG. 34 includes a logarithmic-scale X-axis 3410 depicting radiation concentration using sun units; a linear-scale Y-axis 3415 depicting efficiency of solar cells using units of percent; and different lines 3421 3422 3423 3424 3425 3426, each depicting a different type of photovoltaic cell.

FIG. 34 depicts simulation results for a 3D VMJ cell based on pre-patterned macro-pores spaced 50 μm apart, which is the same distance as between trenches in the 2D case.

The lines depicting the efficiency of different pore depths, lines 3421 3422 3423 3424 3425 corresponding to pore depths of 90, 50, 35, 10 and 0 microns respectively, show that increasing pore depth improves conversion efficiency, and defers peak efficiency to a higher radiation concentration.

In the example embodiment of FIG. 34, for high pore depth, the efficiency peak is at a concentration of above 1000 suns. A limiting case of the example 3D model, in which the pore depth is zero, corresponds roughly to a back contact cell [19].

The line showing highest efficiency has a pore depth of 90 μm, which is very close to the active layer thickness of the simulation model, which is 100 μm, indicating that the pores almost reach the front surface. The highest efficiency value predicted by the simulations of this example is about 30%, possibly indicating that VMJ cells of both 2D and 3D designs, under concentrated radiation, offer a potential of higher efficiency than horizontal junction cells.

### EXPERIMENTAL MEASUREMENTS

A VJ test Chip

Arrays of 2D VJ's were fabricated in a SOI wafer with a 50 μm thick active layer.

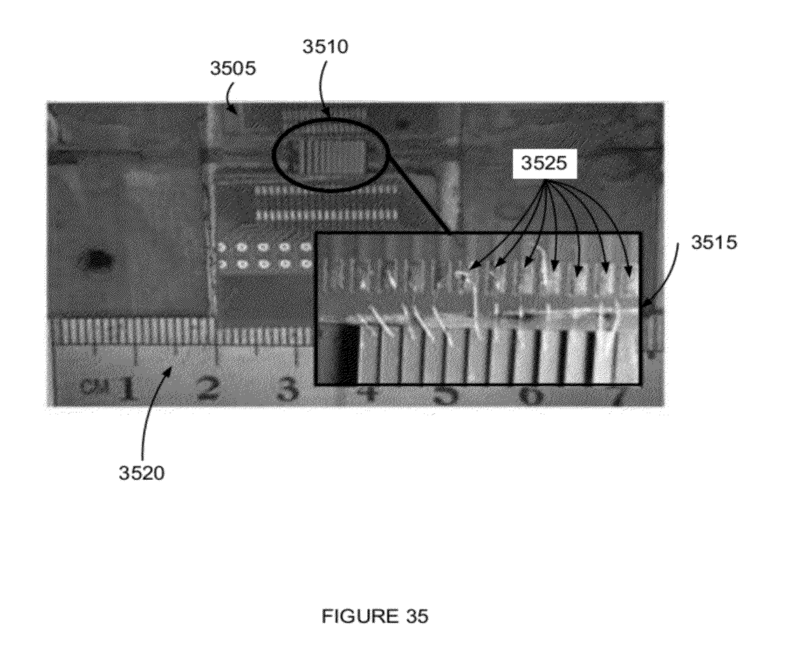

Reference is now made to FIG. 35, which is an image of an array of vertical junction cells produced according to an example embodiment of the invention, mounted on a chip carrier.

FIG. 35 depicts a fabricated array 3510 of 10 single VJ's with a junction width varying between 50 and 250 μm, separated by 600 μm wide metal-coated trenches. FIG. 35 also depicts an enlargement 3515 of the image of the array 3510.

The array 3510 is mounted on a chip carrier 3505. Metallized trench contact areas in the array 3510 are wire-bonded to external contacts 3525, allowing separate electrical measurement of the output of each junction in the array 3510.

A ruler 3520 is also depicted in FIG. 35, to allow approximating sizes within the image of FIG. 35.

A Characterization System

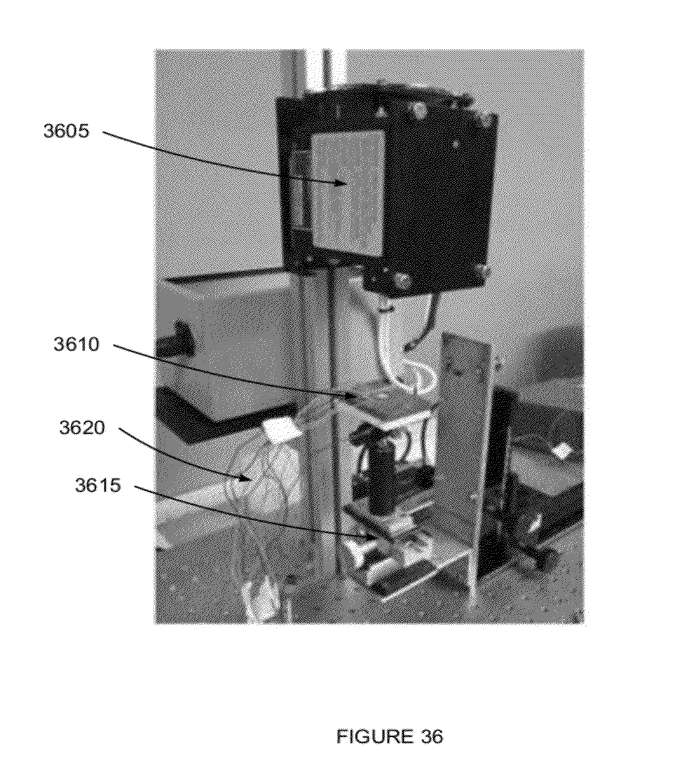

Reference is now made to FIG. 36, which is an image of an experimental setup for characterizing the array of FIG. 35.

An example experiment setup is depicted in FIG. 36, including:

a Perkin Elmer Cermax PE300C-10F Xenon lamp 3605, for irradiating the array of FIG. 35 as a solar simulator;

a water-cooled chip-carrier 3610 located near the focus of the solar simulator;

positioning stages 3615 to move the chip carrier relative to the focus; and

a water-cooled plate with a 5.5×0.45 mm slit (not shown), allowing the illumination of a single VJ within the array.

A VJ test chip is mounted on the chip carrier and connected via individual contacts 3620 to a Keithley 2602A I-V tester (not shown). The positioning stages 3615 allow motion of the chip relative to the slit, for positioning a chosen VJ from the array beneath the slit.

Efficiency vs. Junction Widths

The characterization system described above with reference to FIG. 36 provided experimental results showing efficiency of different junction widths.

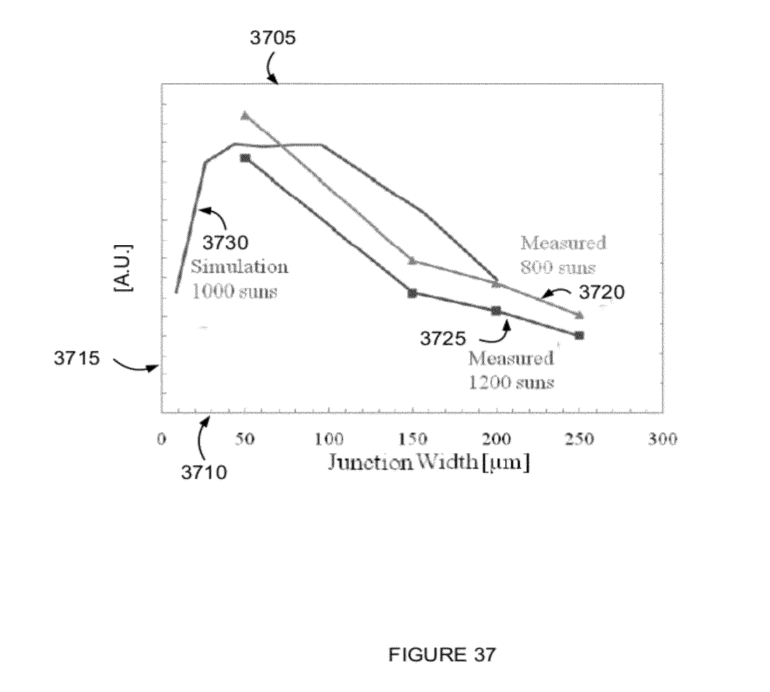

Reference is now made to FIG. 37, which is a simplified graph 3705 illustrating measured and simulated efficiency of VJ cells produced in accordance with an example embodiment of the invention, vs. junction width.

The graph 3705 of FIG. 37 includes an X-axis 3710 of Junction Width, in units of μm, and a Y-axis 3715 of normalized in arbitrary units (A.U.).

FIG. 37 depicts measured data and simulation data normalized to show that both sets of data exhibit the same behavior.

The graph 3705 of FIG. 37 depicts two lines of experimental results of efficiency vs. junction width: a first line 3720 for a radiation concentration of 800 suns, and a second line 3725 for a radiation concentration of 1200 suns, as measured by the experimental setup of FIG. 36. A higher efficiency is observed at a narrow junction of 50 μm width.

The graph 3705 of FIG. 37 also depicts a third line 3730 of simulation model predictions for a similar radiation concentration of 1000 suns, which shows a similar effect of a higher efficiency at about 50 μm junction width, and declining efficiency at higher junction widths.

Previous, prior art, attempts at producing VMJ cells employed much wider junctions [18]. The above-described experiments and simulations potentially show that non-optimal junction geometry was responsible for the lower conversion efficiencies obtained in the prior art. The above-described experimentation and simulation teach that optimization of the junction width in accordance with an embodiment of the present invention, optionally using smaller dimensions, can potentially improve performance of VMJ cells. The smaller dimensions may be produced by monolithic techniques, which provide a potential saving in production costs.

Some Conclusions from the Above-Mentioned Experiments and Simulations

2D and 3D configurations of a Si VMJ high-voltage cell for concentrating PV have been described above. Based on a detailed simulation model, the conversion efficiency of such cells under high concentration can reach about 30%. The cells can also sustain higher radiation concentrations than conventional horizontal junction cells. The above simulation shows that a junction width smaller than that of previous VMJ cells provides better efficiency. A junction width of about 50 μm (junction width for 2D, pore distance for 3D) has shown to have better efficiency than that of wider junctions, in the above-described experimental setup.

Experimental measurements on 2D junctions under concentrated light support this prediction. Realization of such small dimensions can use monolithic fabrication technologies.

The experimental and simulation results show that optimizing cell geometry, in particular a smaller width compared to prior art cells, and optimizing the thickness of the active layer (see the range of thickness described above), provide a potential advantage in efficiency.

The cell dimensions provided above are for silicon. Other materials are expected to show a similar behavior, but optimal dimensions will be different. The optimal dimensions for the other materials may be found by experimental and/or simulation as described above.

### General

It is expected that during the life of a patent maturing from this application many relevant photovoltaic cells will be developed and the scope of the term photovoltaic cell is intended to include all such new technologies a priori.

As used herein the term “about” refers to ±10%.

The terms “comprises”, “comprising”, “includes”, “including”, “having” and their conjugates mean “including but not limited to”. This term encompasses the terms “consisting of” and “consisting essentially of”.

The phrase “consisting essentially of” means that the composition or method may include additional ingredients and/or steps, but only if the additional ingredients and/or steps do not materially alter the basic and novel characteristics of the claimed composition or method.

As used herein, the singular form “a”, an and “the” include plural references unless the context clearly dictates otherwise. For example, the term “a compound” or “at least one compound” may include a plurality of compounds, including mixtures thereof.

The words “example” and “exemplary” are used herein to mean “serving as an example, instance or illustration”. Any embodiment described as an “example” or “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. A monolithic semiconductor solar cell comprising:
a semiconductor layer comprising a plurality of pores, wherein:
walls of the pores are doped, forming vertical junctions between the walls of the pores and a bulk of the semiconductor;
the pores each contain a conductor which is in electrical contact with the walls of the pores; and
the conductors of the pores are electrically interconnected to provide an output voltage of the solar cell.

2. The solar cell of claim 1 in which some of the walls of the pores are doped with P+ doping, and some of the walls of the pores are doped with N+ doping.

3. The solar cell of claim 2, in which nearest neighbors of a P+ doped pore are N+ doped pores, and nearest neighbors of an N+ doped pore are P+ doped pores.

4. The solar cell of claim 2, in which at least some of the conductors of the P+ doped pores are electrically interconnected to each other, forming a parallel connection of one polarity of the vertical junctions, and at least some of the conductors of the N+ doped pores are electrically interconnected to each other, forming a separate parallel connection of another polarity of the vertical junctions.

5. The solar cell of claim 2, comprising at least two groups of pores, each group comprising at least one P+ pore and at least one N+ pore, where each of the groups is electrically isolated from the other groups by isolation trenches in the semiconductor.

6. The solar cell of claim 5, in which the conductors of the P+ doped pores in one group are electrically interconnected to conductors of the N+ doped pores in another group, the interconnections alternating P+ and N+ doped pores, forming a serial connection of vertical junctions.

7. The solar cell of claim 1, in which the depth of the pores is substantially equal to a thickness of the semiconductor layer.

8. The solar cell of claim 1, in which the depth of the pores is less than a thickness of the semiconductor layer.

9. A method of manufacturing a monolithic semiconductor solar cell comprising:
forming a plurality of pores in the semiconductor;
doping walls of the pores, forming vertical junctions between the walls of the pores and a bulk of the semiconductor;
adding a conductor in contact with the doped walls in each pore;
electrically interconnecting the conductors to provide an output voltage of the solar cell.

10. The method of claim 9, in which the doping comprises doping some of the walls of the pores with P+ doping, and some of the walls of the pores with N+ doping.

11. The method of claim 10, in which the electrically interconnecting comprises electrically interconnecting at least some of the conductors of the P+ doped pores to each other, forming a parallel connection of vertical junctions, and electrically interconnecting at least some of the conductors of the N+ doped pores to each other, forming a separate parallel connection of vertical junctions.

12. The method of claim 10, further comprising:
producing isolation trenches in the semiconductor, to electrically isolate between a plurality of groups of pores,
each group of pores comprising at least one P+ doped pore and at least one N+ doped pore.

13. The method of claim 12, in which the electrically interconnecting comprises electrically interconnecting the conductors of the P+ doped pores in one group of pores to the conductors of the N+ doped pores in another group of pores, the interconnections alternating P+ and N+ doped pores, forming a serial connection of vertical junctions.

14. A monolithic semiconductor solar cell comprising:
a semiconductor layer comprising a plurality of trenches, wherein:
walls of the trenches are doped, forming vertical junctions between the walls of the trenches and a bulk of the semiconductor;
the trenches each contain a conductor which is in electrical contact with the walls of the trenches; and
the conductors of the trenches are electrically interconnected to provide an output voltage of the solar cell.

15. A monolithic solar cell, comprising a plurality of semiconductor junctions defining an interface between two materials, said junctions adapted to generate an electric potential when a surface thereof is exposed to electromagnetic radiation and wherein:
said junctions are vertical junctions with at least 30% of said interface being within 30 degrees of a radiation incidence angle thereon;
said junctions are separated by generally vertical trenches; and
the sides of a trench are differently doped.

16. A cell according to claim 15, wherein said junctions are arranged so at least 99% of said surface is exposed to said radiation and within a diffusion length from said interface of the junction.

17. A cell according to claim 15, wherein said cell includes at least some junctions connected in series as groups and said groups connected in parallel.

18. A cell according to claim 15, wherein said cell generates a voltage per unit cell length of at least 50 V/cm.

19. A cell according to claim 15, comprising a second plurality of junctions with different sensitivity to electromagnetic radiation and wherein said plurality of junctions and said second plurality of junctions are arranged in at least two layers.

20. A cell according to claim 19, where the number of junctions in one layer is different from the number of junctions in a second layer, and the numbers of junctions are adjusted so that the overall voltage provided by the first and second layers is substantially equal.

21. A monolithic solar cell, comprising a plurality of semiconductor junctions defining an interface between two materials, said junctions adapted to generate an electric potential when exposed to electromagnetic radiation and said junctions are arranged so that at least 95% of the surface of both materials that are directed to said radiation are exposed to said radiation for each junction and are within a diffusion length from the interface of the materials, wherein said junctions are manufactured together in said monolithic form.

22. A cell according to claim 21, wherein said materials are thick enough to absorb at least 80% of radiation impinging thereon in a bandgap wavelength thereof.

23. A monolithic solar cell, comprising a plurality of junctions defining an interface between two materials formed about walls of pores formed in a substrate.

24. A cell according to claim 23, wherein the pores are arranged in a plurality of patterns enabling currents flow between a junction and junctions immediately around said junction.

25. A method of manufacturing a solar cell, comprising: monolithically manufacturing a plurality of vertical junctions; and forming metal contacts sandwiched between the junctions.

26. A method of manufacturing a solar cell, comprising:
monolithically manufacturing a at least two sets of a plurality of spaced apart vertical junctions;
interleaving the plurality of junctions of each set in the space between the junctions in another set; and
forming electrical conducting contacts sandwiched between the junctions.

27. A method of manufacturing a solar cell, comprising:
monolithically manufacturing a plurality of vertical junctions formed in pores arranged in a plurality of patterns enabling currents flow between a junction and junctions immediately around said junction.

28. A method according to claim 27 comprising forming electrical conducting contacts inside the pores.

29. A method of manufacturing a solar cell, comprising:
forming a plurality of pores or trenches in a substrate; and
differently doping different parts of a same pore or trench.
